(19) United States
(12) Patent Application Publication
(10) Pub. No.: US 2018/0182966 A1
(43) Pub. Date: Jun. 28, 2018

(54) POLYMER, COMPOSITION INCLUDING THE POLYMER, AND ORGANIC LIGHT-EMITTING DEVICE INCLUDING THE POLYMER

(71) Applicant: Samsung Electronics Co., Ltd., Suwon-si (KR)

(72) Inventors: Norihito ISHII, Kanagawa (JP); Katsunori SHIBATA, Kanagawa (JP); Fumiaki KATO, Kanagawa (JP)

(21) Appl. No.: 15/851,983

(22) Filed: Dec. 22, 2017

(30) Foreign Application Priority Data
Dec. 27, 2016 (JP) 2016-253757
Nov. 13, 2017 (KR) 10-2017-0150709

(51) Int. Cl. H01L 51/00; C08G 61/12

(52) U.S. Cl. CPC H01L 51/0039; C08G 61/128; H01L 51/5206; H01L 51/0043; C08G 61/124

(57) ABSTRACT

A polymer including at least one first repeating unit represented by Formula 1:

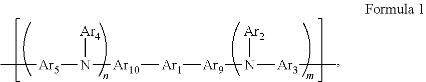

wherein, in Formula 1, groups and variables are the same as described in the specification.

### CROSS-REFERENCE TO RELATED APPLICATIONS

This application claims priority to Japanese Patent Application No. 2016-253757, filed on Dec. 27, 2016, in the Japanese Patent Office and Korean Patent Application No. 10-2017-0150709, filed on Nov. 13, 2017, in the Korean Intellectual Property Office, and all the benefits accruing therefrom under 35 U.S.C. § 119, the contents of which are incorporated herein in their entireties by reference.

### BACKGROUND

### 1. Field

One or more embodiments relate to a polymer, a composition including the polymer, and an organic light-emitting device including the polymer.

### 2. Description of the Related Art

Organic light-emitting devices (OLEDs) are self-emission devices, which have wide viewing angles, high contrast ratios, short response times, display excellent characteristics such as brightness, driving voltage, and response speed, and produce full-color images.

In an example, an organic light-emitting device includes an anode, a cathode, and an organic layer that is disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in the emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

Aspects of the present disclosure provide a polymer, a composition including the polymer for use in an organic light-emitting device, and an organic light-emitting device including the polymer.

Additional aspects will be set forth in part in the description which follows and, in part, will be apparent from the description, or may be learned by practice of the presented embodiments.

An aspect of the present disclosure provides a polymer including at least one first repeating unit represented by Formula 1:

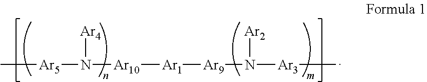

In Formula 1,

Ar₂ and Ar₄ may each independently be selected from hydrogen, a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted monovalent C₅-C₃₀ heterocyclic group, and —N(Q₁)(Q₂),

at least one of Ar₂ and Ar₄ may be selected from a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted monovalent C₅-C₃₀ heterocyclic group, and —N(Q₁)(Q₂),

Ar₃ and Ar₅ may each independently be selected from a substituted or unsubstituted divalent C₆-C₃₀ carbocyclic group and a substituted or unsubstituted divalent C₅-C₃₀ heterocyclic group,

at least one of Ar₂ and Ar₃ may optionally be linked to Ar₉ to form a ring structure,

at least one of Ar₄ and Ar₅ may optionally be linked to Ar₁₀ to form a ring structure,

n and m may each independently be an integer greater than or equal to 1,

when m is two or more, two or more groups Ar₂ may be identical to or different from each other, when m is two or more, two or more groups Ar₃ may be identical to or different from each other, when n is two or more, two or more groups Ar₄ may be identical to or different from each other, and when n is two or more, two or more groups Ar₅ may be identical to or different from each other,

Ar₉ and Ar₁₀ may each independently be selected from a single bond, a substituted or unsubstituted divalent C₆-C₃₀ carbocyclic group, and a substituted or unsubstituted divalent C₅-C₃₀ heterocyclic group,

at least one of Ar₉ and Ar₁₀ may be selected from a substituted or unsubstituted divalent C₆-C₃₀ carbocyclic group and a substituted or unsubstituted divalent C₅-C₃₀ heterocyclic group, and

An may be a divalent group represented by Formula 1-1,

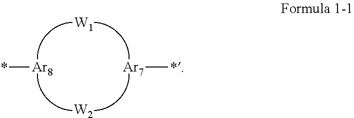

In Formula 1-1,

W₁ and W₂ may each independently be a divalent linking group represented by —X—Z— or —Z—X—,

X may be a substituted or unsubstituted C₁-C₂₀ alkylene group, a substituted or unsubstituted C₂-C₂₀ alkenylene group, a substituted or unsubstituted C₂-C₂₀ alkynylene group, a substituted or unsubstituted C₃-C₁₀ cycloalkylene group, a substituted or unsubstituted C₃-C₁₀ cycloalkenylene group, or a substituted or unsubstituted C₆-C₆₀ arylene group,

Z may be a single bond, —O—, —C(═O)—, —N(Q₃)-, —S—, —S(═O)₂—, or —Si(Q₃)(Q₄)-,

Ar₇ and Ar₈ may each independently be selected from a substituted or unsubstituted trivalent C₆-C₃₀ carbocyclic group and a substituted or unsubstituted trivalent C₅-C₃₀ heterocyclic group,

at least one of Ar₂ to Ar₅ may optionally be linked to Ar₇ or Ar₈ to form a ring structure,

Q₁ and Q₂ may each independently be selected from hydrogen, a substituted or unsubstituted C₁-C₂₀ alkyl group, and a substituted or unsubstituted C₆-C₃₀ aryl group,

Q₃ and Q₄ may each independently be selected from hydrogen and a substituted or unsubstituted C₁-C₈ alkyl group, and

* and *′ each indicate a binding site to a neighboring atom.

Another aspect of the present disclosure provides a polymer including at least one first repeating unit represented by Formula 1 and further including at least one of a second repeating unit represented by Formula 2 and a third repeating unit represented by Formula 3:

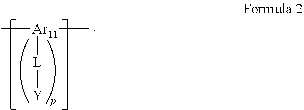

In Formula 2,

Ar₁₁ may be a substituted or unsubstituted (2+p)-valent C₆-C₃₀ carbocyclic group or a substituted or unsubstituted (2+p)-valent C₅-C₃₀ heterocyclic group,

L may be a single bond, a substituted or unsubstituted C₁-C₂₄ alkylene group, or a substituted or unsubstituted phenylene group,

Y may be a crosslinking group,

p may be an integer greater than or equal to 1, and

when p is two or more, two or more groups L may be identical to or different from each other, and when p is two or more, two or more groups Y may be identical to or different from each other.

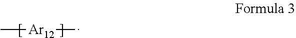

In Formula 3,

Ar₁₂ may be a substituted or unsubstituted divalent C₆-C₃₀ carbocyclic group or a substituted or unsubstituted divalent C₅-C₃₀ heterocyclic group.

Another aspect of the present disclosure provides a composition including: the polymer described above; and a solvent or a dispersion medium.

Another aspect of the present disclosure provides an organic light-emitting device including:

a first electrode;

a second electrode; and

an organic layer disposed between the first electrode and the second electrode, wherein the organic layer includes an emission layer, and

wherein the organic layer includes the polymer described above.

Another aspect of the present disclosure provides a method of manufacturing an organic light-emitting device, which includes a first electrode, a second electrode, and an organic layer disposed between the first electrode and the second electrode, wherein the organic layer includes an emission layer and a layer including the polymer, the method including forming a layer including the polymer by solution coating using a composition including the polymer and a solvent or a dispersion medium.

### BRIEF DESCRIPTION OF THE DRAWING

These and/or other aspects will become apparent and more readily appreciated from the following description of the embodiments, taken in conjunction with the FIGURE which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

The term “x to y” indicating a range, as used herein, means “greater than or equal to x and less than or equal to y”.

Also, the operations and physical properties have been measured at a temperature of 20° C. to 25° C. and a relative humidity of 40% RH to 50% RH, unless otherwise specified.

In an embodiment, a polymer is provided. The polymer according to an embodiment may include at least one first repeating unit represented by Formula 1:

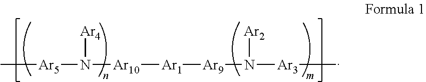

In Formula 1,

Ar₂ and Ar₄ may each independently be selected from hydrogen, a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted monovalent C₅-C₃₀ heterocyclic group, and —N(Q₁)(Q₂), and

at least one of Ar₂ and Ar₄ may each independently be selected from a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted monovalent C₅-C₃₀ heterocyclic group, and —N(Q₁)(Q₂).

Q₁ and Q₂ may each independently be selected from hydrogen, a substituted or unsubstituted C₁-C₂₀ alkyl group, and a substituted or unsubstituted C₆-C₃₀ aryl group.

In an embodiment, at least one of Ar₂ and Ar₄ in Formula 1 may be a substituted or unsubstituted C₆-C₃₀ aryl group or a substituted or unsubstituted monovalent C₅-C₃₀ heterocyclic group, but embodiments of the present disclosure are not limited thereto.

In an embodiment, at least one of Ar₂ and Ar₄ in Formula 1 may be a substituted or unsubstituted C₆-C₃₀ aryl group, but embodiments of the present disclosure are not limited thereto. When at least one of Ar₂ and Ar₄ is a substituted or unsubstituted C₆-C₃₀ aryl group, the polymer including the first repeating unit represented by Formula 1 has a high triplet energy level.

In an embodiment, in terms of the improvement in triplet energy level, Ar₂ and Ar₄ in Formula 1 may each independently be a substituted or unsubstituted C₆-C₃₀ aryl group, but embodiments of the present disclosure are not limited thereto.

In an embodiment, in Formula 1, Ar₂ and Ar₄ may each independently be selected from:

hydrogen, a methyl group, an ethyl group, an n-propyl group, an iso-propyl group, an n-butyl group, an iso-butyl group, a sec-butyl group, a tert-butyl group, an n-pentyl group, an isopentyl group, a tert-pentyl group, a neo-pentyl group, a 1,2-dimethylpropyl group, an n-hexyl group, an iso-hexyl group, a 1,3-dimethylbutyl group, a 1-iso-propylpropyl group, a 1,2-dimethylbutyl group, an n-heptyl group, a 1,4-dimethylpentyl group, a 3-ethylpentyl group, a 2-methyl-1-iso-propylpropyl group, a 1-ethyl-3-methylbutyl group, an n-octyl group, a 2-ethylhexyl group, a 3-methyl-1-iso-propylbutyl group, a 2-methyl-1-iso-propyl group, a 1-tert-butyl-2-methylpropyl group, an n-nonyl group, a 3,5,5-trimethyldecyl group, an n-decyl group, an iso-decyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, an n-eicosyl group, an n-heneicosyl group, an n-docosyl group, an n-tricosyl group, an n-tetracosyl group, a methoxy group, an ethoxy group, a propoxy group, an iso-propoxy group, an n-butoxy group, an iso-butoxy group, a sec-butoxy group, tert-butoxy group, an n-pentoxy group, an iso-pentoxy group, a tert-pentoxy group, a neo-pentoxy group, an n-hexyloxy group, an iso-hexyloxy group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, a cyclopropyl group, a cyclobutyl group, a cyclopentyl group, a cyclohexyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group; and

a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryloxy group, a C₆-C₃₀ arylthio group, and a C₅-C₃₀ heteroaryl group, but embodiments of the present disclosure are not limited thereto.

In one or more embodiments, in Formula 1, Are and Ar₄ may each independently be a substituted or unsubstituted phenyl group, but embodiments of the present disclosure are not limited thereto.

In Formula 1, Ar₃ and Ar₅ may each independently be selected from a substituted or unsubstituted divalent C₆-C₃₀ carbocyclic group, and a substituted or unsubstituted divalent C₅-C₃₀ heterocyclic group.

In an embodiment, in Formula 1, Ar₃ and Ar₅ may each independently be selected from:

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahygrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoxazolylene group, a benzimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, an imidazopyrimidinylene group, and an imidazopyridinylene group; and

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group, but embodiments of the present disclosure are not limited thereto.

In an embodiment, at least one of Ar₃ and Ar₅ in Formula 1 may each independently be a substituted or unsubstituted divalent C₆-C₃₀ carbocyclic group, but embodiments of the present disclosure are not limited thereto. When at least one of Ar₃ and Ar₅ is each independently a substituted or unsubstituted divalent C₆-C₃₀ carbocyclic group, the polymer including the first repeating unit represented by Formula 1 has a high triplet energy level.

In one or more embodiments, at least one of Ar₃ and Ar₅ in Formula 1 may each independently be a substituted or unsubstituted phenylene group, but embodiments of the present disclosure are not limited thereto.

In Formula 1, at least one of Ar₂ and Ar₃ may optionally be linked to Ar₉ to form a ring structure, and at least one of Ar₄ and Ar₅ may optionally be linked to Ar₁₀ to form a ring structure.

In an embodiment, in Formula 1, Ar₃ and Ar₉ and/or Ar₅ and Ar₁₀ may be linked to form a ring structure, but embodiments of the present disclosure are not limited thereto.

In Formula 1, m indicates the number of repetitions of moieties represented by *—N(Ar₂)—Ar₃—*′, and m may be an integer greater than or equal to 1. When m is two or more, two or more groups Ar₂ may be identical to or different from each other, and when m is two or more, two or more groups Ar₃ may be identical to or different from each other.

In Formula 1, n indicates the number of repetitions of moieties represented by *—N(Ar₄)—Ar₅—*′, and n may be an integer greater than or equal to 1. When n is two or more, two or more groups Ar₄ may be identical to or different from each other, and when n is two or more, two or more groups Ar₅ may be identical to or different from each other.

In an embodiment, in terms of the improvement in triplet energy level, m and n may each independently be an integer from 1 to 4, but embodiments of the present disclosure are not limited thereto.

In an embodiment, m and n may each be 1, but embodiments of the present disclosure are not limited thereto.

In Formula 1, Ar₉ and Ar₁₀ may each independently be selected from a single bond, a substituted or unsubstituted divalent C₆-C₃₀ carbocyclic group, and a substituted or unsubstituted divalent C₅-C₃₀ heterocyclic group, and

at least one of Ar₉ and Ar₁₀ may be selected from a substituted or unsubstituted divalent C₆-C₃₀ carbocyclic group and a substituted or unsubstituted divalent C₅-C₃₀ heterocyclic group.

When at least one of Ar₉ and Ar₁₀ is selected from a substituted or unsubstituted divalent C₆-C₃₀ carbocyclic group and a substituted or unsubstituted divalent C₅-C₃₀ heterocyclic group, the polymer including the first repeating unit represented by Formula 1 may have a high triplet energy level, and an organic light-emitting device including the polymer may have high efficiency and a long lifespan.

In an embodiment, in Formula 1, Ar₉ and Ar₁₀ may each independently be selected from:

a single bond, a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahygrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoxazolylene group, a benzimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, an imidazopyrimidinylene group, and an imidazopyridinylene group; and

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group, but embodiments of the present disclosure are not limited thereto.

In an embodiment, in Formula 1, Ar₉ and Ar₁₀ may each independently be selected from:

a phenylene group and a carbazolylene group; and

a phenylene group and a carbazolylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group, but embodiments of the present disclosure are not limited thereto.

In one or more embodiments, in Formula 1, Ar₉ and Ar₁₀ may each independently be selected from divalent groups represented by Formulae 5-1 to 5-5, but embodiments of the present disclosure are not limited thereto:

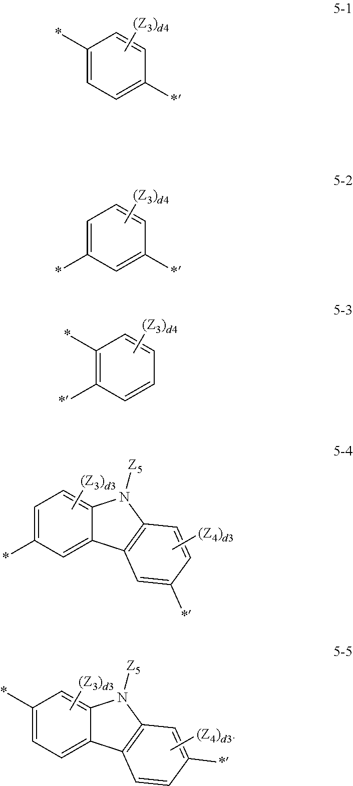

In Formulae 5-1 to 5-5,

Z₃ to Z₅ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,

d3 may be an integer from 1 to 3,

d4 may be an integer from 1 to 4, and

* and *′ each indicate a binding site to a neighboring atom.

In one or more embodiments, Z₅ in Formulae 5-4 and 5-5 may be selected from a phenyl group and a phenyl group substituted with a C₁-C₂₀ alkyl group, but embodiments of the present disclosure are not limited thereto.

An in Formula 1-1 may be a divalent group represented by Formula 1-1:

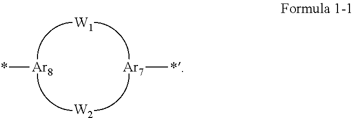

W₁ and W₂ in Formula 1-1 may each independently be a divalent linking group represented by —X—Z— or —Z—X—.

X may be a substituted or unsubstituted C₁-C₂₀ alkylene group, a substituted or unsubstituted C₂-C₂₀ alkenylene group, a substituted or unsubstituted C₂-C₂₀ alkynylene group, a substituted or unsubstituted C₃-C₁₀ cycloalkylene group, a substituted or unsubstituted C₃-C₁₀ cycloalkenylene group, or a substituted or unsubstituted C₆-C₆₀ arylene group, and Z may be a single bond, —O—, —C(═O)—, —N(Q₃)-, —S—, —S(═O)₂—, or —Si(Q₃)(Q₄)-.

Q₃ and Q₄ may each independently be selected from hydrogen and a substituted or unsubstituted C₁-C₈ alkyl group, but embodiments of the present disclosure are not limited thereto.

In an embodiment, in terms of the improvement in triplet energy level, W₁ and W₂ in Formula 1-1 may each independently be a divalent group represented by —(CR₁R₂)_{q}—.

R₁ and R₂ may each independently be selected from hydrogen, a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted C₅-C₃₀ heteroaryl group, and —N(Q₁)(Q₂).

In the above formula, q indicates the number of repetitions of moieties represented by —(CR₁R₂)—, and q may be an integer from 1 to 4. When q is two or more, two or more groups —(CR₁R₂)— may be identical to or different from each other.

In an embodiment, q may be 2, but embodiments of the present disclosure are not limited thereto.

Ar₇ and Ar₈ in Formula 1-1 may each independently be selected from a substituted or unsubstituted trivalent C₆-C₃₀ carbocyclic group and a substituted or unsubstituted trivalent C₅-C₃₀ heterocyclic group.

In an embodiment, Ar₇ and Ar₈ in Formula 1-1 may each independently be selected from a substituted or unsubstituted trivalent aromatic C₆-C₃₀ carbocyclic group and a substituted or unsubstituted trivalent aromatic C₅-C₃₀ heterocyclic group.

In an embodiment, in Formula 1-1, Ar₇ and Ar₈ may each independently be selected from:

a benzene group, a pentalene group, an indene group, a naphthalene group, an azulene group, a heptalene group, an indacene group, an acenaphthalene group, a fluorene group, a spiro-fluorene group, a phenalene group, a phenanthrene group, an anthracene group, a fluoranthene group, a pyrene group, a chrysene group, a naphthacene group, a picene group, a perylene group, a pentaphenylene group, a hexacene group, a pyrrole group, an imidazole group, a pyrazole group, a pyridine group, a pyrazine group, a pyrimidine group, a pyridazine group, an iso-indole group, an indole group, an indazole group, a purine group, a quinoline group, an isoquinoline group, a benzoquinoline group, a phthalazine group, a naphthyridine group, a quinoxaline group, a quinazoline group, a cinnoline group, a carbazole group, a phenanthridine group, an acridine group, a phenanthroline group, a phenazine group, a benzoxazole group, a benzimidazole group, a furan group, a benzofuran group, a thiophene group, a benzothiophene group, a thiazole group, an isothiazole group, a benzothiazole group, an iso-oxazole group, an oxazole group, a triazole group, a tetrazole group, an oxadiazole group, a triazine group, a dibenzofuran group, a dibenzothiophene group, a benzocarbazole group, a dibenzocarbazole group, an imidazopyrimidine group, and an imidazopyridine group; and

a benzene group, a pentalene group, an indene group, a naphthalene group, an azulene group, a heptalene group, an indacene group, an acenaphthalene group, a fluorene group, a spiro-fluorene group, a phenalene group, a phenanthrene group, an anthracene group, a fluoranthene group, a pyrene group, a chrysene group, a naphthacene group, a picene group, a perylene group, a pentaphenylene group, a hexacene group, a pyrrole group, an imidazole group, a pyrazole group, a pyridine group, a pyrazine group, a pyrimidine group, a pyridazine group, an iso-indole group, an indole group, an indazole group, a purine group, a quinoline group, an isoquinoline group, a benzoquinoline group, a phthalazine group, a naphthyridine group, a quinoxaline group, a quinazoline group, a cinnoline group, a carbazole group, a phenanthridine group, an acridine group, a phenanthroline group, a phenazine group, a benzoxazole group, a benzimidazole group, a furan group, a benzofuran group, a thiophene group, a benzothiophene group, a thiazole group, an isothiazole group, a benzothiazole group, an iso-oxazole group, an oxazole group, a triazole group, a tetrazole group, an oxadiazole group, a triazine group, a dibenzofuran group, a dibenzothiophene group, a benzocarbazole group, a dibenzocarbazole group, an imidazopyrimidine group, and an imidazopyridine group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group, but embodiments of the present disclosure are not limited thereto.

In an embodiment, in Formula 1-1, Ar₇ and Ar₈ may each independently be a substituted or unsubstituted trivalent C₆-C₃₀ carbocyclic group, but embodiments of the present disclosure are not limited thereto.

In one or more embodiments, in Formula 1-1, Ar₇ and Ar₈ may each independently be selected from:

a benzene group; and

a benzene group substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group, but embodiments of the present disclosure are not limited thereto.

Formula 1-1 may have a cyclophane structure in which Ar₇ and Ar₈ are linked by crosslinking having a chain structure of two or more carbons or the like.

In an embodiment, Formula 1-1 may be a divalent group represented by Formula 1-2, but embodiments of the present disclosure are not limited thereto:

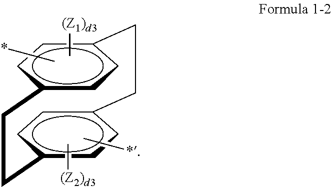

In Formula 1-2,

Z₁ and Z₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,

d3 may be an integer from 1 to 3, and

* and *′ each indicate a binding site to a neighboring atom.

In one or more embodiments, Formula 1-1 may be selected from divalent groups represented by Formulae 4-1 to 4-4, but embodiments of the present disclosure are not limited thereto:

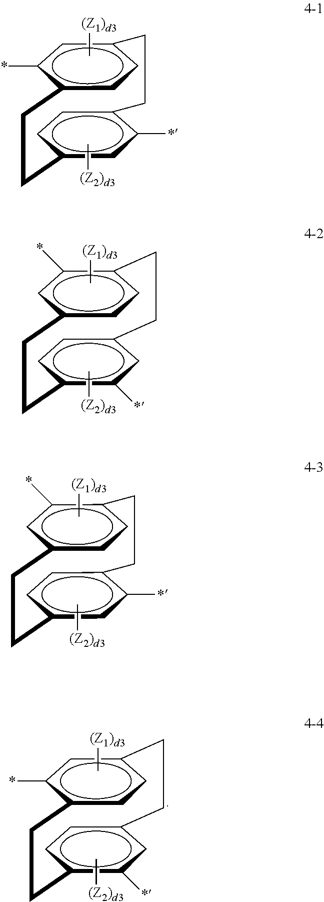

In Formulae 4-1 to 4-4,

Z₁ and Z₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,

d3 may be an integer from 1 to 3, and

* and *′ each indicate a binding site to a neighboring atom.

In an embodiment, Formula 1-1 may be selected from divalent groups represented by Formulae 4-1 to 4-4, and Ar₉ and Ar₁₀ may each independently be selected from divalent groups represented by Formulae 5-1 to 5-5, but embodiments of the present disclosure are not limited thereto.

In an embodiment, a divalent group represented by *—Ar₉—Ar₁—Ar₁₀—*′ in Formula 1 may be a divalent group represented by Formula 7-1 or 7-2, but embodiments of the present disclosure are not limited thereto:

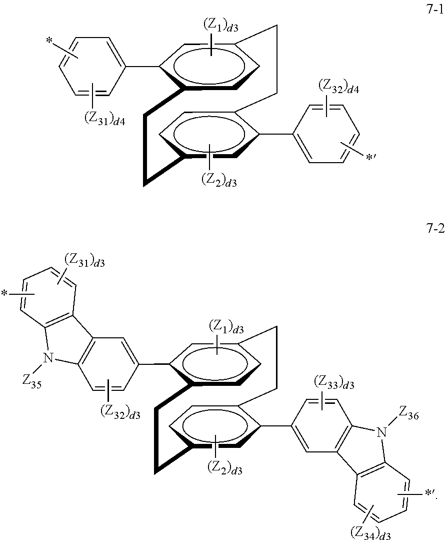

In Formulae 7-1 and 7-2,

Z₂, and Z₃₁ to Z₃₆ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,

d3 may be an integer from 1 to 3,

d4 may be an integer from 1 to 4, and

* and *′ each indicate a binding site to a neighboring atom.

In one or more embodiments, Z₃₅ and Z₃₆ in Formula 7-2 may each independently be selected from a C₁-C₂₀ alkyl group, a C₆-C₃₀ aryl group, a C₆-C₃₀ aryl group substituted with a C₁-C₂₀ alkyl group, and a C₅-C₃₀ heteroaryl group.

In an embodiment, Formula 1 may be represented by one of Formula 1A to 1F, but embodiments of the present disclosure are not limited thereto:

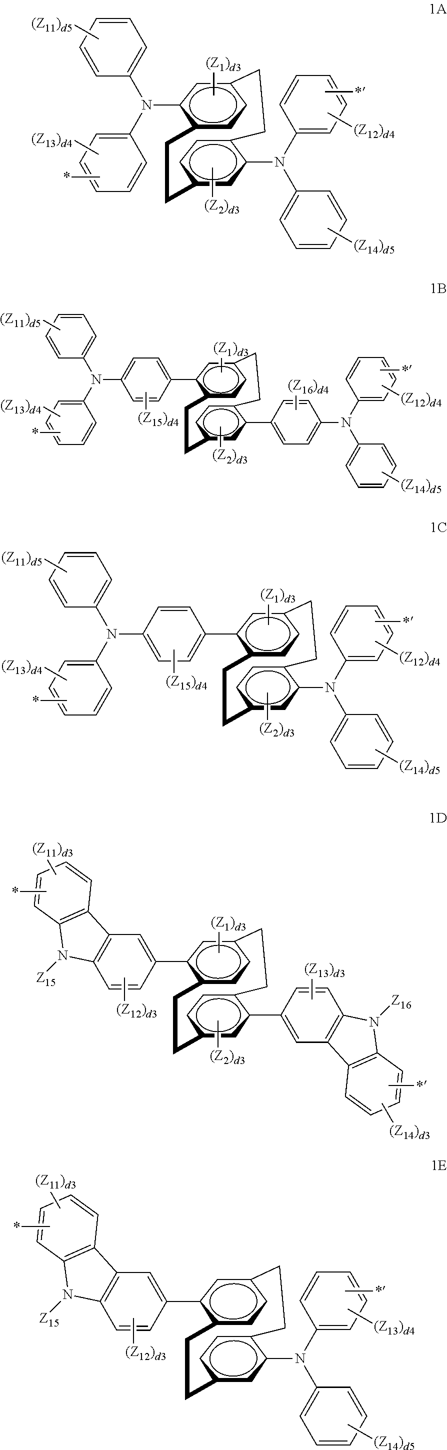

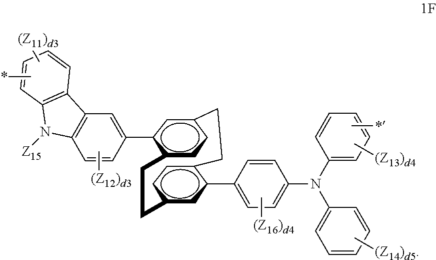

In Formulae 1A to 1F,

Z₁₁ to Z₁₆ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,

d3 may be an integer from 1 to 3,

d4 may be an integer from 1 to 4,

d5 may be an integer from 1 to 5, and

* and *′ each indicate a binding site to a neighboring atom.

The polymer may further include at least one of a second repeating unit represented by Formula 2 and a third repeating unit represented by Formula 3:

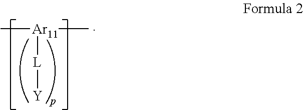

Ar₁₁ in Formula 2 may be a substituted or unsubstituted (2+p)-valent C₆-C₃₀ carbocyclic group or a substituted or unsubstituted (2+p)-valent C₅-C₃₀ heterocyclic group.

In an embodiment, Ar₁₁ in Formula 2 may be a substituted or unsubstituted (2+p)-valent aromatic C₆-C₃₀ carbocyclic group or a substituted or unsubstituted (2+p)-valent aromatic C₅-C₃₀ heterocyclic group, but embodiments of the present disclosure are not limited thereto.

In an embodiment, Ar₁₁ in Formula 2 may be selected from:

a phenylene group, a fluorenylene group, a dibenzofuranylene group, a dibenzothiophenylene group, and a triphenylenylene group; and

a phenylene group, a fluorenylene group, a dibenzofuranylene group, a dibenzothiophenylene group, and a triphenylenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a fluorenyl group, a dibenzofuranyl group, a dibenzothiophenyl group, and a triphenylenyl group, but embodiments of the present disclosure are not limited thereto.

In an embodiment, Ar₁₁ in Formula 2 may be selected from groups represented by Formulae 8-1 to 8-4, but embodiments of the present disclosure are not limited thereto:

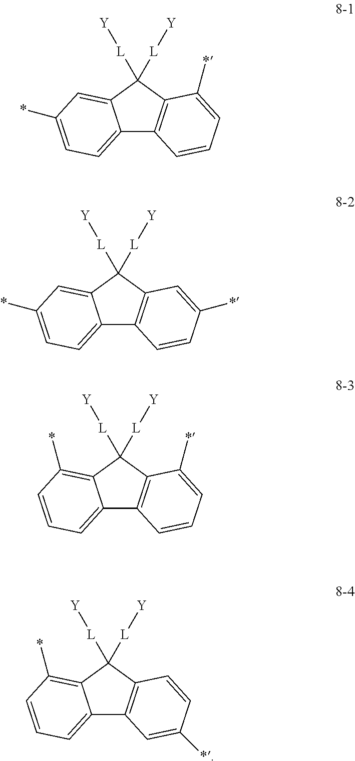

In an embodiment, Ar₁₁ in Formula 2 may be represented by Formula 8-2, but embodiments of the present disclosure are not limited thereto.

L in Formula 2 may be a single bond, a substituted or unsubstituted C₁-C₂₄ alkylene group, or a substituted or unsubstituted phenylene group.

In an embodiment, L in Formula 2 may be a single bond or a C₁-C₈ alkylene group, but embodiments of the present disclosure are not limited thereto.

In one or more embodiments, L in Formula 2 may be a single bond, a methylene group, an ethylene group, or a trimethylene group, but embodiments of the present disclosure are not limited thereto.

In one or more embodiments, L in Formula 2 may be a single bond or a trimethylene group, but embodiments of the present disclosure are not limited thereto.

Y in Formula 2 may be a crosslinking group.

In an embodiment, Y in Formula 2 may be selected from groups represented by Formulae 9-1 to 9-8, but embodiments of the present disclosure are not limited thereto:

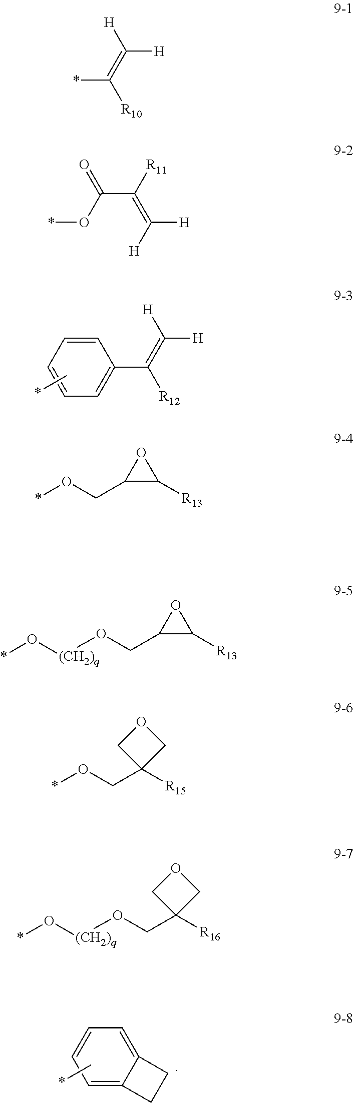

In Formulae 9-1 to 9-8,

R₁₀ to R₁₆ may each independently be selected from hydrogen and a substituted or unsubstituted C₁-C₁₀ alkyl group,

q may be an integer from 1 to 10, and

* indicates a bond to a neighboring atom.

In one or more embodiments, Y in Formula 2 may be a bicyclo[4,2,0]octa-1,3,5-trienyl group or a vinyl group. In this case, the stability and the electrochemical stability of the crosslinking structure may be improved. In one or more embodiments, Y in Formula 2 may be a cyclic ether group such as an epoxy group and an oxetane group, or a vinyl ether group. In this case, the cross-linkability of the polymer including the second repeating unit represented by Formula 2 may be improved.

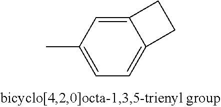

In Formula 2, p indicates the number of substituents represented by *-L-Y, and p may be an integer greater than or equal to 1. When p is two or more, two or more groups L may be identical to or different from each other, and when p is two or more, two or more groups Y may be identical to or different from each other.

In an embodiment, p may be an integer from 1 to 3, but embodiments of the present disclosure are not limited thereto.

In one or more embodiments, p may be 2, but embodiments of the present disclosure are not limited thereto.

In an embodiment, Formula 2 may be represented by one of the following formulae, but embodiments of the present disclosure are not limited thereto:

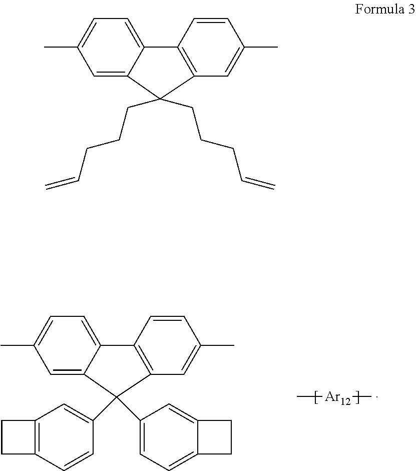

In Formula 3, Ar₁₂ may be a substituted or unsubstituted divalent C₆-C₃₀ carbocyclic group or a substituted or unsubstituted divalent C₅-C₃₀ heterocyclic group.

In an embodiment, in Formula 3, Ar₁₂ may be a substituted or unsubstituted divalent aromatic C₆-C₃₀ carbocyclic group or a substituted or unsubstituted divalent aromatic C₅-C₃₀ heterocyclic group, but embodiments of the present disclosure are not limited thereto.

In an embodiment, in Formula 3, Ar₁₂ may be selected from:

a phenylene group, a naphthylene group, a phenanthrenylene group, a triphenylene group, a pyridinylene group, a pyrimidinylene group, and a triazinylene group; and

a phenylene group, a naphthylene group, a phenanthrenylene group, a triphenylene group, a pyridinylene group, a pyrimidinylene group, and a triazinylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₄ alkyl group, a C₁-C₂₄ alkoxy group, a phenyl group, a naphthyl group, a phenanthrenyl group, a triphenyl group, a pyridinyl group, a pyrimidinyl group, and a triazinyl group, but embodiments of the present disclosure are not limited thereto.

In an embodiment, in Formula 3, Ar₁₂ may be selected from:

a phenylene group; and

a phenylene group substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₄ alkyl group, a C₁-C₂₄ alkoxy group, and a phenyl group, but embodiments of the present disclosure are not limited thereto.

In one or more embodiments, Formula 3 may be represented by Formula 3A, but embodiments of the present disclosure are not limited thereto:

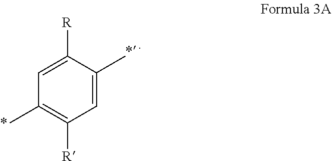

In Formula 3A, R and R′ each independently indicate a C₁-C₂₄ alkyl group.

At least one substituent of the substituted C₁-C₂₀ alkyl group, the substituted C₃-C₁₆ cycloalkyl group, the substituted C₁-C₂₀ alkoxy group, the substituted C₃-C₁₆ cycloalkoxy group, the substituted C₆-C₃₀ aryl group, the substituted C₆-C₃₀ aryloxy group, the substituted C₇-C₄₀ aralkyl group, the substituted monovalent C₅-C₃₀ heterocyclic group, the substituted C₁-C₂₀ alkylene group, the substituted C₂-C₂₀ alkenylene group, the substituted C₂-C₂₀ alkynylene group, the substituted C₃-C₁₆ cycloalkylene group, the substituted C₃-C₁₆ cycloalkenylene group, the substituted C₆-C₃₀ arylene group, the substituted divalent C₆-C₃₀ carbocyclic group, the substituted divalent C₅-C₃₀ heterocyclic group, the substituted trivalent C₆-C₃₀ carbocyclic group, and the substituted trivalent C₅-C₃₀ heterocyclic group is selected from:

deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and

—Si(Q₃₁)(Q₃₂)(Q₃₃), —N(Q₃₄)(Q₃₅), and —B(Q₃₆)(Q₃₇),

wherein Q₁₁ to Q₁₇, Q₂₁ to Q₂₇, and Q₃₁ to Q₃₇ are each independently selected from hydrogen, a C₁-C₆₀ alkyl group, a C₂-C₆₀ alkenyl group, a C₂-C₆₀ alkynyl group, a alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

In order to manufacture a large organic light-emitting device at a lower cost, solution coating may be used. The solution coating has high material utilization efficiency and facilitates the manufacture of a large organic light-emitting device, as compared with vacuum deposition. Also, the solution coating has an advantage in that vacuum equipment is not required and equipment cost is low. For example, JP 2013-018946 A discloses the use of a charge transport material having a polymeric structure.

However, since a triplet energy level of the polymer disclosed in JP 2013-018946 A is not sufficiently high, the polymer cannot achieve desired current efficiency.

The polymer according to the embodiment may have a high triplet energy level. Also, the polymer is suitable for film formation using solution coating, and an organic light-emitting device including the polymer may provide high current efficiency and have a long lifespan.

The polymer includes the first repeating unit represented by Formula 1. By introducing a unit in which a pi-electron conjugated system is laminated in the first repeating unit, the bond of main chain is broken to increase the triplet energy level of the polymer, thereby achieving high current efficiency. Also, since the first repeating unit includes an amine-based unit, high charge mobility can be achieved. Therefore, when the polymer according to the embodiment is used as a hole transport material, the deterioration effect of electrons is reduced, thereby improving the lifespan of the device.

Also, since the second repeating unit includes a crosslinking group, a crosslinking reaction may be caused by heating and/or irradiation of active energy rays. Such a crosslinking reaction makes it possible to form a film having a high durability so that the film is not dissolved in a solvent, and another layer may be stacked and coated thereon by using solution coating. That is, even if another layer is formed on the layer with the polymer including the second repeating unit, the polymer layer is not or hardly dissolved in the solvent when another layer is coated. Therefore, the film formation can be facilitated.

Also, the polymer including the third repeating unit has excellent solubility in the solvent. Therefore, the use of the polymer including the third repeating unit can facilitate film formation using solution coating. Also, the flatness of the film is improved to increase luminescent efficiency.

The polymer according to the embodiment may include at least one second repeating unit. The polymer according to the embodiment may include two or more second repeating units, but embodiments of the present disclosure are not limited thereto.

The polymer according to the embodiment may include at least one third repeating unit.

The composition of the second repeating unit of the polymer according to the embodiment is not particularly limited. The second repeating unit may be in a range of about 1% to about 50%, for example, about 2% to about 20%, based on the total repeating unit constituting the polymer, but embodiments of the present disclosure are not limited thereto. Also, when the polymer includes two or more second repeating units, an amount of the second repeating unit means a total amount of the second repeating units.

The composition of the third repeating unit of the polymer according to the embodiment is not particularly limited. The third repeating unit may be in a range of about 10% to about 90%, for example, about 20% to about 80%, based on the total repeating unit constituting the polymer, but embodiments of the present disclosure are not limited thereto. Also, when the polymer includes two or more third repeating units, an amount of the third repeating unit means a total amount of the third repeating units.

The polymer according to the embodiment may include the first repeating unit, and optionally, at least one of the second repeating unit and the third repeating unit (that is, a homopolymer including the first repeating unit or a 2- or 3-membered copolymer including the first repeating unit, and the second repeating unit and/or the third repeating unit), or may include the first repeating unit, the second repeating unit, and the third repeating unit (that is, a 3-membered copolymer including the first repeating unit, the second repeating unit, and the third repeating unit). When the polymer is a copolymer, the structure of the polymer is not particularly limited. The polymer may be one of a random copolymer, an alternating copolymer, a periodic copolymer, and a block copolymer, but embodiments of the present disclosure are not limited thereto.

The end of the main chain of the polymer according to the embodiment is not particularly limited. The end of the main chain of the polymer may be appropriately defined according to a kind of a material used, and is generally a hydrogen atom, but embodiments of the present disclosure are not limited thereto.

The polymer may be synthesized by using a known organic synthesis method. For example, the polymer may be prepared by a polymerization reaction using at least one monomer A represented by Formula 21. Also, the polymer may be prepared by a polymerization reaction using at least one monomer A represented by Formula 21, and at least one monomer B represented by Formula 22 and/or at least one monomer C represented by Formula 23. Also, the monomer used for the polymerization of the polymer may be synthesized by a known method, and the structure of the monomer may be identified by NMR and LC-MS:

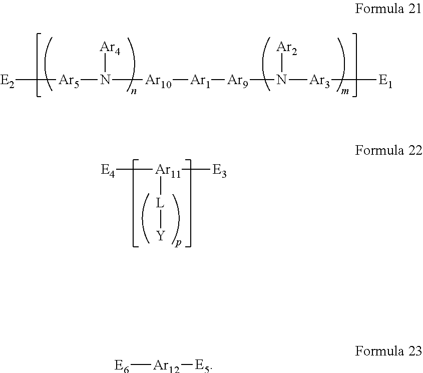

In Formulae 21 to 23, Ar₁ to Ar₅, Ar₉ to Ar₁₂, L, Y, and p are the same as described in Formulae 1 to 3, and E₁ to E₆ are each independently selected from —F, —Cl, —Br, —I, and a group represented by Formula 24:

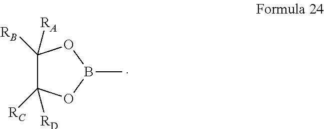

R_{A} to R_{D} in Formula 24 may each independently be selected from a methyl group, an ethyl group, and a propyl group.

A concentration of the monomer in the solvent (a total of monomers when a plurality of monomers are used) may be in a range of about 5 percent by weight (wt %) to about 90 wt % based on 100% of the reaction solution. For example, the concentration of the monomer in the solvent may be in a range of about 10 wt % to about 80 wt %, but embodiments of the present disclosure are not limited thereto.

A polymerization temperature may be in a range of about 40° C. to about 100° C. in terms of molecular weight control, but embodiments of the present disclosure are not limited thereto.

The polymerization reaction may be progressed for about 30 minutes to about 24 hours, but embodiments of the present disclosure are not limited thereto.

The solvent, to which the monomer is added, may be deaerated before a polymerization initiator is added. For example, the deaeration processing may be freeze deaeration, deaeration using inert gas such as nitrogen gas, or the like, but embodiments of the present disclosure are not limited thereto.

The polymer synthesis method described above may be easily recognized by those of ordinary skill in the art by referring to Synthesis Examples provided below.

Composition for Manufacturing Organic Light-Emitting Device

Another aspect of the present disclosure provides a composition for manufacturing an organic light-emitting device, which includes the polymer and a solvent or a dispersion medium.

The polymer described above, or the material for the organic light-emitting device, which includes the polymer, has high charge mobility, and thus, may be used as a hole injection material, a hole transport material and/or a material for forming an emission layer. In an embodiment, the polymer and the material for the organic light-emitting device, which includes the polymer may be used as a hole injection material or a hole transport material (for example, a hole transport material) in terms of hole transport ability.

In an embodiment, the composition for manufacturing the organic light-emitting device may include the polymer; and at least one material selected from a hole transport material, an electron transport material, and a light-emitting material.

In an embodiment, the light-emitting material may be an organometallic complex compound, but embodiments of the present disclosure are not limited thereto.

The composition for manufacturing the organic light-emitting device may include the polymer and the solvent or the dispersion medium. The composition for manufacturing the organic light-emitting device may be used for, for example, forming each layer of the organic light-emitting device by solution coating.

Another aspect of the present disclosure provides a method of manufacturing an organic light-emitting device, which includes a first electrode, a second electrode, and an organic layer disposed between the first electrode and the second electrode, wherein the organic layer includes an emission layer and a layer including the polymer, the method including forming the layer including the polymer by solution coating using the composition including the polymer and the solvent or the dispersion medium.

Organic Light-Emitting Device

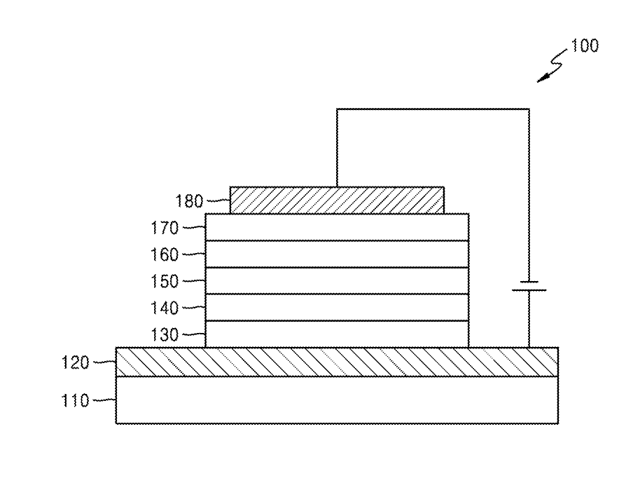

Hereinafter, an organic light-emitting device according to an embodiment will be described in detail. The FIG. 1s a schematic view of an organic light-emitting device 100 according to an embodiment.

The organic light-emitting device 100, illustrated in the FIGURE, includes a substrate 110, a first electrode 120, a hole injection layer 130, a hole transport layer 140, an emission layer 150, an electron transport layer 160, an electron injection layer 170, and a second electrode 180, but embodiments of the present disclosure are not limited thereto.

The organic light-emitting device may have a first electrode/single film having a hole injection function and a hole transport function/emission layer/electron transport layer/second electrode structure or a first electrode/single film having a hole injection function and a hole transport function/emission layer/electron transport layer/electron injection layer/second electrode structure.

The polymer may be included in at least one organic layer disposed between the first electrode 120 and the second electrode 180. For example, the polymer may be included in the hole injection layer 130, the hole transport layer 140, or the emission layer 140. In an embodiment, the polymer may be included in the hole injection layer 130 or hole transport layer 140, but embodiments of the present disclosure are not limited thereto. For example, in terms of the long lifespan and the high efficiency of the organic light-emitting device, the polymer may be included in the hole transport layer 140, but embodiments of the present disclosure are not limited thereto.

The polymer may be more suitable for an organic light-emitting device manufactured by solution coating.

The organic layer including the polymer may be formed by solution coating. For example, the organic layer including the polymer may be deposited by using solution coating, such as spin coating, casting, micro gravure coating, gravure coating, bar coating, roll coating, wire bar coating, dip coating, spry coating, screen printing, flexographic printing, offset printing, and ink-jet printing. Also, as the solvent used in solution coating, any solvents may be used as long as the polymer can be dissolved therein. For example, the solvent may be selected from toluene, xylene, diethyl ether, chloroform, ethyl acetate, methylene chloride, tetrahydrofuran, acetone, acetonitrile, N,N-dimethylformamide, dimethylsulfoxide, anisole, hexamethylphosphoric triamide, methyl benzoate, ethyl benzoate, phenylcyclohexane, and tetrahydronaphthalene. In an embodiment, the solvent may be selected from toluene and tetrahydrofuran. Solvents may be used solely or in combination. The monomer used for the polymerization of the polymer according to the embodiment has high solubility in the solvent. The solvent is used in an amount such that a concentration of the dissolved polymer is in a range of about 0.1 wt % to about 10 wt %, for example, about 0.5 wt % to about 5 wt %, but embodiments of the present disclosure are not limited thereto.

A method of forming layers other than the organic layer including the polymer is not particularly limited. For example, the layers other than the organic layer including the polymer may be deposited by vacuum deposition, or may be formed by solution coating.

The substrate 110 may be any suitable substrate generally used in organic light-emitting devices. For example, the substrate 110 may be a glass substrate, a semiconductor substrate such as a silicon substrate, or a transparent plastic substrate.

The first electrode 120 may be, for example, an anode. The first electrode 120 may be formed on the substrate 110 by deposition or sputtering. For example, the first electrode 120 may be formed of a material with a high work function selected from a metal, an alloy, and a conductive compound. The first electrode 120 may be formed as a transmissive electrode including indium tin oxide (In₂O₃—SnO₂, ITO), indium zinc oxide (In₂O₃—ZnO, IZO), tin oxide (SnO₂), or zinc oxide (ZnO), each having excellent transparency and conductivity. Also, the first electrode 120 may be formed as a reflective electrode including magnesium (Mg) or aluminum (Al).

The hole injection layer 130 may be formed on the first electrode 120. The hole injection layer 130 may facilitate hole injection from the first electrode 120. The hole injection layer 130 may be formed to have a thickness of about 10 nanometers (nm) to about 1,000 nm, for example, about 10 nm to about 100 nm.

The hole injection layer 130 may include a known material, for example, poly(ether ketone)-containing triphenylamine (TPAPEK), 4-iso-propyl-4′-methyldiphenyliodonium tetrakis(pentafluorophenyl)borate (PPBI), N,N′-diphenyl-N,N′-bis-[4-(phenyl-m-tolylamino)-phenyl]-biphenyl-4,4′-diamine (DNTPD), phthalocyanine compound such as copper phthalocyanine, 4,4′,4″-tris(3-methylphenyl phenylamino)triphenylamine (m-MTDATA), N,N′-di(1-naphthyl)-N,N′-diphenylbenzidine (NPB), 4,4′,4″-tris{N, N-diphenylamino}trisphenylamine (TDATA), 4,4′,4″-tris(N, N-2-naphthylphenylamino)triphenylamine (2-TNATA), polyaniline/dodecylbenzene sulfonic acid (PAN I/DBSA), poly(3,4-ethylenedioxythiophene)/poly(4-styrenesulfonate) (PEDOT/PSS), polyaniline/camphor sulfonic acid (PAN I/CSA), and polyaniline)/poly(4-styrene sulfonate) (PANI/PSS).

The hole transport layer 140 may be formed on the hole injection layer 130. The hole transport layer 140 includes a hole transport material that transports holes and has a thickness of about 10 nm to about 150 nm.

The hole transport layer 140 may be formed of the polymer by using solution coating. According to the solution coating, a film may be efficiently formed over a large area by using the polymer capable of improving current efficiency and emission lifespan of the organic light-emitting device 100.

The hole transport layer 140 may include, in addition to the above-described polymer, a known material, for example, 1,1-bis[(di-4-tolylamino)phenyl]cyclohexane (TAPC), a carbazole derivative such as N-phenylcarbazole or polyvinylcarbazole, N,N′-bis(3-methylphenyl)-N,N-diphenyl-[1,1-biphenyl]-4,4′-diamine (TPD), 4,4′,4″-tris(N-carbazolyl)triphenylamine (TCTA), or N, N′-bis(naphthalen-2-yl)-N, N′-bis(phenyl)-benzidine (NPB).

The emission layer 150 may be formed on the hole transport layer 140. The emission layer 150 emits light such as phosphorescence or fluorescence, and may be formed on the hole transport layer 140 by using vacuum deposition, spin coating, or ink-jet printing. The emission layer 150 may have a thickness of about 10 nm to about 60 nm.

The emission layer 150 includes a known light-emitting material. However, the emission layer 150 may include a light-emitting material capable of emitting light from triplet excitons (that is, emission by photoluminescence). In this case, the emission lifespan of the organic light-emitting device 100 may be further improved.

Also, the emission layer 150 may include other host materials, for example, 9,9′-diphenyl-3,3′-bi[9H-carbazole], tris(8-quinolinolato)aluminum (Alq₃), 1,3-bis(carbazole)benzene (mCP), 4,4′-N,N′-dicabazole-biphenyl (CBP), poly(n-vinylcabazole (PVK), 9,10-di(naphthalene-2-yl)anthracene (AND), TCTA, 1,3,5-tris(N-phenylbenzimidazole-2-yl)benzene (TPBI), 3-tert-butyl-9,10-di(naphth-2-yl)anthracene (TBADN), distyrylarylene (DSA), 4.4′-bis(9-carbazol)-2,2′-dimethylbiphenyl (dmCBP), or 2,4,6-tris(diphenylamino)-1,3,5-triazine.

The emission layer 150 may be formed as an emission layer that emits light of a specific color. For example, the emission layer 150 may be formed as a red emission layer, a green emission layer, and a blue emission layer.

When the emission layer 150 is a blue emission layer, a known material may be used as a blue dopant. For example, a perylene and a derivative thereof, iridium (Ir) complex such as bis[2-(4,6-difluorophenyl)pyridinate]picolinateiridium(III) (Flrpic), or the like may be used.

Also, when the emission layer 150 is a red emission layer, a known material may be used as a red dopant. Examples of the red dopant may include rubrene and a derivative thereof, 4-(dicyanomethylene)-2-methyl-6-[p-(dimethylamino)styryl]-4H-pyran (DCm) and a derivative thereof, an iridium complex such as bis(1-phenylisoquinoline)(acetylacetonate)iridium(III) (Ir(piq)₂(acac)), an osmium (Os) complex, and a platinum complex.

When the emission layer 150 is a green emission layer, a known material may be used as a green dopant. Examples of the green dopant may include coumarin and a derivative thereof, and iridium complex such as tris(2-phenylpyridine)iridium(III) (Ir(DP_{Y})₃), tris(2-(3-p-xylyl)phenyl)pyridine iridium(III) (TEG), and tris(acetylacetonato)iridium(III) (Ir(acac)₃).

The electron transport layer 160 may be formed on the emission layer 150. The electron transport layer 160 includes an electron transport material that transports electrons, and may be formed on the emission layer 150 by using vacuum deposition, spin coating, or ink-jet printing. The electron transport layer 160 may be formed to have a thickness of, for example, about 15 nm to about 50 nm.

The electron transport layer 160 may include a known electron transport material, for example, (8-quinolinato)lithium (LiQ), tris(8-quinolinato)aluminium (Alq₃), and a compound having a nitrogen-containing aromatic ring. Examples of the compound having the nitrogen-containing aromatic ring may include a compound including a pyridine ring such as 1,3,5-tri[(3-pyridyl)-phen-3-yl]benzene, a compound including a triazine ring such as 2,4,6-tris(3′-(pyridin-3-yl)biphenyl-3-yl)-1,3,5-triazine, and a compound including an imidazole such as 2-(4-(N-phenylbenzoimidazolyl-1-yl-phenyl)-9,10-dinaphthylanthracene. As materials for forming the electron transport layer, a commercially available item or a synthetic item may be used. Examples of the commercially available item may include KLET-01, KLET-02, KLET-03, KLET-10, and KLET-M1 (available from Chemipro Kasei Corporation). The materials for forming the electron transport layer may be used solely or in combination.

The electron injection layer 170 may be formed on the electron transport layer 160. The electron injection layer 170 may facilitate electron injection from the second electrode 180, and may be formed on the electron transport layer 160 by using vacuum deposition or the like. The electron injection layer 170 may be formed to have a thickness of about 0.3 nm to about 9 nm.

The electron injection layer 170 may include a known electron injection material, for example, (8-quinolinato)lithium (LiQ), lithium fluoride (LiF), sodium chloride (NaCl), cesium fluoride (CsF), lithium oxide (Li₂O), and barium oxide (BaO).

The second electrode 180 may be formed on the electron injection layer 170. The second electrode 180 may be, for example, a cathode, and may be formed of a material with a low work function selected from a metal, an alloy, and a conductive compound. The second electrode 180 may be formed as a reflective electrode including a metal, for example, lithium (Li), magnesium (Mg), aluminum (Al), or calcium (Ca), or an alloy such as aluminum-lithium (Al—Li), magnesium-indium (Mg—In), or magnesium-silver (Mg—Ag). Also, the second electrode 180 may be formed as a transmissive electrode having a thickness of about 20 nm or less and including indium tin oxide (ITO), or indium zinc oxide (IZO).

The organic light-emitting device 100 may be a top-emission organic light-emitting device or a bottom-emission organic light-emitting device.

An example of the configuration of the organic light-emitting device 100 according to the embodiment has been described, but the configuration of the organic light-emitting device according to an embodiment is not limited to the above example.

The organic light-emitting device 100 according to an embodiment may be manufactured by using various known configurations. For example, the organic light-emitting device 100 may not include one or more of the hole injection layer 130, the hole transport layer 140, the electron transport layer 160, and the electron injection layer 170, and may further include other layers. Also, each layer of the organic light-emitting device 100 may be a single layer or multiple layers.

In order to prevent diffusion of triplet excitons or holes to the electron transport layer 160, the organic light-emitting device 100 may further include a hole blocking layer between the hole transport layer 140 and the emission layer 150. The hole blocking layer may be formed using, for example, an oxadiazole derivative a triazole derivative, or a phenanthroline derivative.

The term “C₁-C₂₀ alkyl group” as used herein refers to a linear or branched saturated aliphatic hydrocarbon monovalent group having 1 to 20 carbon atoms, and examples thereof include a methyl group, an ethyl group, a propyl group, an iso-butyl group, a sec-butyl group, a tert-butyl group, a pentyl group, an iso-amyl group, and a hexyl group. The term “C₁-C₂₀ alkylene group” as used herein refers to a divalent group having the same structure as the C₁-C₂₀ alkyl group.

The term “C₁-C₂₀ alkoxy group” as used herein refers to a monovalent group represented by —OA₁₀₁ (wherein A₁₀₁ is the C₁-C₂₀ alkyl group), and examples thereof include a methoxy group, an ethoxy group, and an iso-propyloxy group.

The term “C₂-C₆₀ alkenyl group” as used herein refers to a hydrocarbon group having at least one carbon-carbon double bond in the middle or at the terminus of the C₂-C₆₀ alkyl group, and examples thereof include an ethenyl group, a propenyl group, and a butenyl group. The term “C₂-C₂₀ alkenylene group” as used herein refers to a divalent group having the same structure as the C₂-C₂₀ alkenyl group.

The term “C₂-C₆₀ alkynyl group” as used herein refers to a hydrocarbon group having at least one carbon-carbon triple bond in the middle or at the terminus of the C₂-C₆₀ alkyl group, and examples thereof include an ethynyl group, and a propynyl group. The term “C₂-C₂₀ alkynylene group” as used herein refers to a divalent group having the same structure as the C₂-C₂₀ alkynyl group.

The term “C₃-C₁₆ cycloalkyl group” as used herein refers to a monovalent saturated hydrocarbon monocyclic group having 3 to 16 carbon atoms, and examples thereof include a cyclopropyl group, a cyclobutyl group, a cyclopentyl group, a cyclohexyl group, and a cycloheptyl group. The term “C₃-C₁₆ cycloalkylene group” as used herein refers to a divalent group having the same structure as the C₃-C₁₆ cycloalkyl group.

The term “C₃-C₁₆ cycloalkenyl group” as used herein refers to a monovalent monocyclic group that has 3 to 16 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₆ cycloalkenylene group” as used herein refers to a divalent group having the same structure as the C₃-C₁₆ cycloalkenyl group.

The term “C₃-C₁₆ cycloalkoxy group” as used herein refers to a monovalent group represented by —OA₁₀₂ (wherein A₁₀₂ is the C₃-C₁₆ cycloalkyl group), and examples thereof include a cyclopropoxy group, a cyclobutoxy group, and a cyclopentoxy group.

The term “C₆-C₃₀ aryl group” as used herein refers to a monovalent group having a carbocyclic aromatic system having 6 to 30 carbon atoms, and a C₆-C₃₀ arylene group used herein refers to a divalent group having a carbocyclic aromatic system having 6 to 30 carbon atoms. Non-limiting examples of the C₆-C₃₀ aryl group include a phenyl group, a naphthyl group, an anthracenyl group, a phenanthrenyl group, a pyrenyl group, and a chrysenyl group. When the C₆-C₃₀ aryl group and the C₆-C₃₀ arylene group each include two or more rings, the rings may be fused to each other.

The term “C₆-C₃₀ aryloxy group” as used herein refers to a monovalent group represented by —OA₁₀₃ (wherein A₁₀₃ is the C₆-C₃₀ aryl group).

The term “C₆-C₃₀ arylthio group” as used herein refers to a monovalent group represented by —SA₁₀₃ (wherein A₁₀₃ is the C₆-C₆₀ aryl group).

The term “C₅-C₃₀ heteroaryl group” as used herein refers to a monovalent group having a carbocyclic aromatic system that has at least one heteroatom selected from N, O, Si, P, and S as a ring-forming atom, in addition to 5 to 30 carbon atoms being involved in the ring formation. The term “C₅-C₆₀ heteroarylene group” as used herein refers to a divalent group having a carbocyclic aromatic system that has at least one heteroatom selected from N, O, Si, P, and S as a ring-forming atom, in addition to 5 to 60 carbon atoms. Non-limiting examples of the C₅-C₃₀ heteroaryl group include a pyridinyl group, a pyrimidinyl group, a pyrazinyl group, a pyridazinyl group, a triazinyl group, a quinolinyl group, and an isoquinolinyl group. When the C₅-C₃₀ heteroaryl group and the C₅-C₃₀ heteroarylene group each include two or more rings, the rings may be condensed with each other.

The term “C₇-C₄₀ aralkyl group” as used herein refers to a monovalent group in which an alkyl group substituted with an aryl group and the sum of the carbon atoms of the constituting groups, i.e., the alkyl group and the aryl group, is 7 to 40. Examples of the C₇-C₄₀ aralkyl group include a benzyl group, a phenylethyl group, a methylbenzyl group, and a naphthylmethyl group.

The term “C₅-C₃₀ carbocyclic group” as used herein refers to a saturated or unsaturated cyclic group having, as a ring-forming atom, 5 to 30 carbon atoms only. The term “C₅-C₃₀ carbocyclic group” as used herein refers to a monocyclic group or a polycyclic group, and, according to its chemical structure, a monovalent, divalent, trivalent, tetravalent, pentavalent, or hexavalent group.

The term “C₅-C₃₀ heterocyclic group” as used herein refers to a saturated or unsaturated cyclic group having, as a ring-forming atom, at least one heteroatom selected from N, O, Si, P, and S other than 5 to 30 carbon atoms. The term “C₅-C₃₀ heterocyclic group” as used herein refers to a monocyclic group or a polycyclic group, and, according to its chemical structure, a monovalent, divalent, trivalent, tetravalent, pentavalent, or hexavalent group.

The term “halogen atom” as used herein may include an atom selected from a fluorine atom, a chlorine atom, a bromine atom, and an iodine atom.

At least one substituent of the substituted C₁-C₂₀ alkyl group, the substituted C₂-C₂₀ alkenyl group, the substituted C₂-C₂₀ alkynyl group, the substituted C₃-C₁₆ cycloalkyl group, the substituted C₃-C₁₆ cycloalkenyl group, the substituted C₁-C₂₀ alkoxy group, the substituted C₃-C₁₆ cycloalkoxy group, the substituted C₆-C₃₀ aryl group, the substituted C₆-C₃₀ aryloxy group, the substituted C₇-C₄₀ aralkyl group, the substituted C₅-C₃₀ heteroaryl group, the substituted C₁-C₂₀ alkylene group, the substituted C₂-C₂₀ alkenylene group, the substituted C₂-C₂₀ alkynylene group, the substituted C₃-C₁₆ cycloalkylene group, the substituted C₃-C₁₆ cycloalkenylene group, the substituted C₆-C₃₀ arylene group, the substituted C₆-C₃₀ carbocyclic group, and the substituted C₅-C₃₀ heterocyclic group may be selected from:

deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-Coo alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and

—Si(Q₃₁)(Q₃₂)(Q₃₃), —N(Q₃₄)(Q₃₅), and —B(Q₃₆)(Q₃₇), and

Q₁₁ to Q₁₇, Q₂₁ to Q₂₇, and Q₃₁ to Q₃₇ may each independently be selected from hydrogen, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Hereinafter, a compound according to embodiments and an organic light-emitting device according to embodiments will be described in detail with reference to Synthesis Examples and Examples. The wording “B was used instead of A” used in describing Synthesis Examples refers to that an identical molar equivalent of B was used in place of A.

Hereinafter, a polymer and an organic light-emitting device according to embodiments are described in detail with reference to Synthesis Examples and Examples. However, the organic light-emitting device is not limited thereto.

### EXAMPLES

A method of measuring a number average molecular weight (Mn) and a weight average molecular weight (Mw) is not particularly limited, and known methods may be applied equally or modified as appropriate. The number average molecular weight (Mn) and the weight average molecular weight (Mw) are values measured by the following method.

Measurement of number average molecular weight (Mn) and weight average molecular weight (Mw)

The weight average molecular weight (Mw) of the polymer was measured under the following conditions by gel permeation chromatography (GPC) using polystyrene as a standard sample.

Analysis apparatus: Product manufactured by Shimadzu Corporation, Product name: Prominence

Column: PLgel MIXED-B manufactured by Polymer Labs

Column temperature: 40° C.

Flow rate: 1.0 milliliters per minute (mL/min)

Dose: 20 microliters (μL)

Solvent: Tetrahydrofuran (THF) (concentration: about 0.05 percent by weight, wt %)

Detector: UV-VIS detector (manufactured by Shimadzu Corporation, Product name: SPD-10AV)

Standard Sample: Polystyrene

### Synthesis Example 1: Synthesis of Compound 1

Compound 1 having the following structure was synthesized according to the following Reaction Scheme.

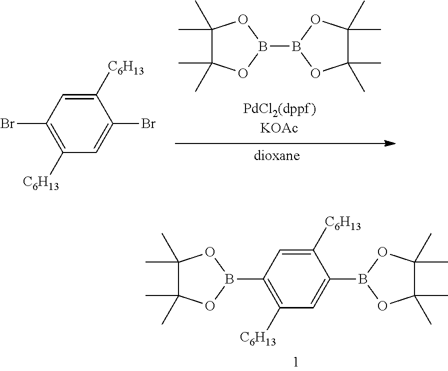

8.08 grams (g) (20.0 millimoles, mmol) of 1,4-dihexyl-2,5-dibromobenzene, 12.19 g (48.0 mmol) of bis(pinacolatodiboron), 0.98 g (1.2 mmol) of 1,1′-bis(diphenylphosphino)ferrocene]palladium(II), 11.78 g (120.0 mmol) of potassium acetate, and 100 milliliters (ml) of dioxane were mixed in a reaction vessel in an argon atmosphere, and the mixture was heated and stirred for 6 hours under reflux.

After the reaction was completed, toluene and water were added to the reaction mixture, followed by liquid separation and washing with water. Sodium sulfate and activated charcoal were added thereto and filtering was performed thereon through Celite (registered trademark). A filtrate obtained therefrom was concentrated to obtain 11.94 g of a crude product.

The obtained product was recrystallized with hexane, and the crystals were washed with methanol. The obtained crystals were dried under reduced pressure to obtain 4.23 g of Compound 1. The structure of the obtained compound 1 was identified by 1H-NMR.

¹H-NMR (300 MHz, CDCl₃): δ=0.95 (t, 6H), 1.39-1.42 (bd, 36H), 1.62 (m, 4H), 2.88 (t, 4H), 7.59 (bd, 2H).

### Synthesis Example 2: Synthesis of Compound 2

Compound 2 having the following structure was synthesized according to the following Reaction Scheme.

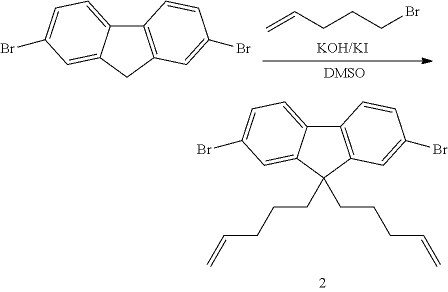

22.7 g (70.0 mmol) of 2,7-dibromofluorene, 21.9 g (147.0 mmol) of 5-bromo-1-pentene, 16.7 g (297.6 mmol) of potassium hydroxide, 1.2 g (7.2 mmol) of potassium iodide, and 170 ml of dimethylsulfoxide were mixed in a reaction vessel in an argon atmosphere, and heated to 80° C. for 4 hours. After the reaction was completed, the reaction mixture was cooled to room temperature. Then, liquid separation was performed thereon by mixing 300 ml of water and 300 ml of toluene. An organic layer obtained therefrom was washed five times by using 300 ml of saturated brine. The obtained organic layer was dried by using sodium sulfate, and a solvent was distilled off. Then, the residue obtained therefrom was purified by column chromatography and recrystallization to obtain 24.1 g of Compound 2. The structure of the obtained Compound 2 was identified by 1H-NMR.

¹H-NMR (270 MHz, CDCl₃): δ=0.69 (t, 4H), 1.83 (m, 4H), 1.93 (m, 4H), 4.85 (d, 4H), 5.56 (m, 2H), 7.44-7.53 (m, 6H).

### Synthesis Example 3: Synthesis of Compound 3

### 3-1. Synthesis of Intermediate 3-1

Intermediate 3-1 having the following structure was synthesized according to the following Reaction Scheme.

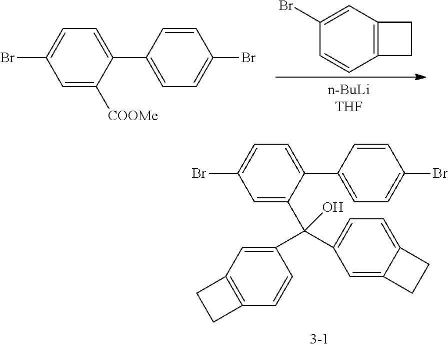 [SMILES: COC(=O)c1cc(Br)ccc1-c1ccc(Br)cc1 ; Brc1ccc2c(c1)CC2 ; OC(c1ccc2c(c1)CC2)(c1ccc2c(c1)CC2)c1cc(Br)ccc1-c1ccc(Br)cc1]

4.1 g (22.4 mmol) of 3-bromobenzocyclobutane and 69 ml of tetrahydrofuran were cooled to −78° C. in a dry ice-methanol bath in a reaction vessel in an argon atmosphere. 16.9 ml of n-butyllithium was added thereto, and the mixture was stirred for 2 hours. A solution in which 4.1 g of methyl 4,4′-dibromo-[1,1′-biphenyl]-2-carboxylic acid ester was dissolved in 12 ml of tetrahydrofuran was added dropwise thereto. The reaction mixture was stirred at a temperature of −78° C. for 2 hours and then stirred at room temperature for 4 hours. 50 ml of water was slowly added thereto while the reaction mixture was cooled in an ice bath. Then, the reaction mixture was transferred to a separatory funnel and washed twice with 30 ml of water. An organic layer obtained therefrom was dried by using magnesium sulfate, and a solid obtained therefrom was filtered and a solution was concentrated to obtain 8.1 g of Intermediate 3-1.

### 3-2. Synthesis of Compound 3

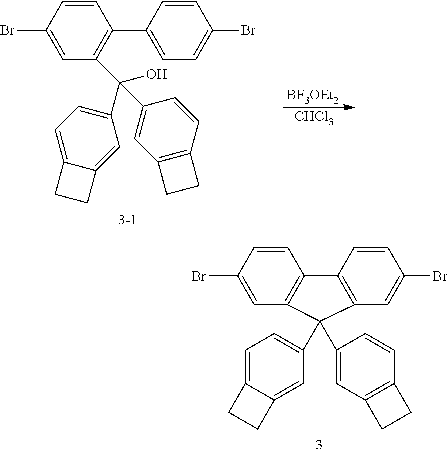 [SMILES: OC(c1ccc2c(c1)CC2)(c1ccc2c(c1)CC2)c1cc(Br)ccc1-c1ccc(Br)cc1 ; "CHCl3" ; Brc1ccc2c(c1)C(c1ccc3c(c1)CC3)(c1ccc3c(c1)CC3)c1cc(Br)ccc1-2 ; "BF3OEt2"]

4.1 g (7.51 mmol) of Intermediate 3-1 and 120 ml of chloroform were added to a reaction vessel in an argon atmosphere, and cooled to 0° C. in an ice bath. Then, 1.0 ml of BF₃Et₂O was added dropwise thereto by using a dropping funnel. After the reaction mixture was stirred for 1 hour, 1.0 ml of BF₃Et₂O was added thereto, and the reaction mixture was stirred for 1 hour, and the mixture was stirred at room temperature for 5 hours. 100 ml of water was added thereto, and the mixture was stirred, and transferred to a separatory funnel. Then, an organic layer was extracted therefrom three times by using 50 ml of chloroform. The extracted organic layer was dried by using sodium sulfate, a solution was concentrated, and 30 ml of chloroform was added thereto. The crystals were obtained by adding 300 ml of methanol thereto while heating under reflux, and the obtained crystals were filtered. The crystals were added to 20 ml of chloroform and heated, and 200 ml of methanol was added thereto, and the mixture was stirred at room temperature for 2 hours. The generated crystals were filtered and dried to obtain 2.0 g of Compound 3. The structure of the obtained Compound 3 was identified by 1H-NMR.

¹H-NMR (300 MHz, CDCl₃): δ 7.56 (d, 2H), 7.49 (d, 2H), 7.45 (dd, 2H), 7.01 (d, 2H), 6.92 (d, 2H), 6.81 (s, 2H), 3.11 (s, 4H).

### Synthesis Example 4: Synthesis of Compound 4

Compound 4 having the following structure was synthesized by the following Reaction Scheme.

### 4-1. Synthesis of Intermediate 4-3

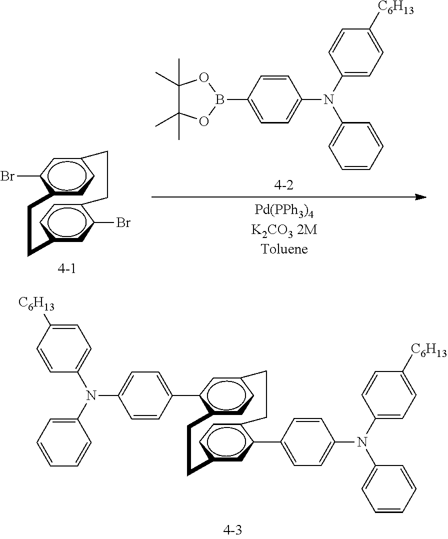

1.50 g (4.14 mmol) of Intermediate 4-1, 4.15 g (9.11 mmol) of Intermediate 4-2, 0.14 g (0.12 mmol) of tetrakis(triphenylphosphine)palladium, and 40 ml of toluene were mixed in a reaction vessel in an argon atmosphere. Then, 6 ml of 2 molar (M) potassium carbonate aqueous solution was added thereto, and the mixture was stirred and heated for 6 hours under reflux. After the reaction was completed, toluene and water were added to the reaction mixture, followed by liquid separation and washing with water. Sodium sulfate and activated charcoal were added thereto and filtering was performed thereon through Celite (registered trademark). A filtrate obtained therefrom was concentrated and purified by column chromatography using hexane and chloroform to obtain 2.1 g (yield: 50%) of Intermediate 4-3. The structure of the obtained Intermediate 4-3 was identified by 1H-NMR.

¹H-NMR (300 MHz, CDCl₃): δ 7.82 (S, 2H), 7.55 (d, 4H). 7.37 (m, 12H), 7.30-7.00 (m, 20H), 7.82 (S, 2H), 2.88 (t, 8H), 2.52 (t, 4H), 1.58-1.29 (m, 16H), 0.88 (t, 6H).

### 4-2. Synthesis of Compound 4

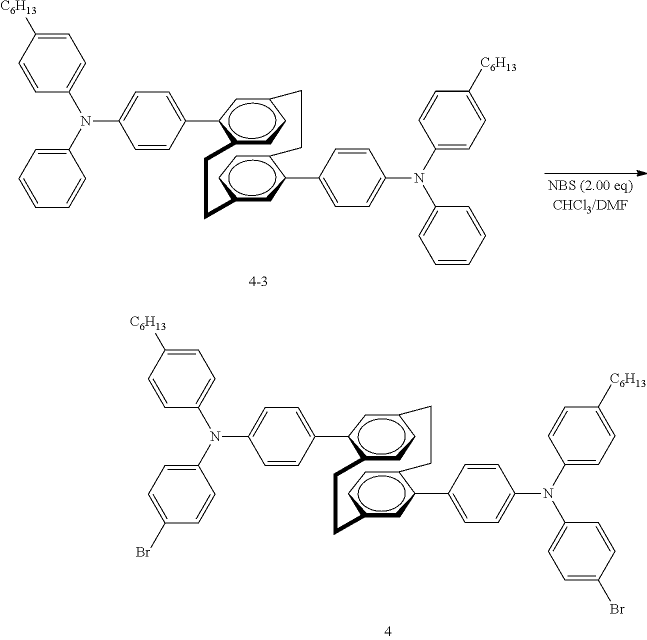

2.0 g (2.3 mmol) of Intermediate 4-3 was added to a reaction vessel in an argon atmosphere, and 40 ml of chloroform was added and dissolved therein. The reaction mixture was cooled to −7° C. in a small amount of dry ice-acetone bath. Then, 1.1 g (6.2 mmol) of N-bromosuccinimide was dissolved in 5 ml of DMF and added dropwise to the reaction mixture over 5 minutes. After 1 hour of reaction, water was added to stop the reaction. The obtained reaction product was purified by column chromatography using hexane and chloroform to obtain 1.8 g (yield: 76%) of Compound 4. The structure of the obtained Compound 4 was identified by 1H-NMR.

¹H-NMR (300 MHz, CDCl₃): δ 7.82 (S, 2H), 7.55 (d, 4H), 7.37 (m, 12H), 7.30-7.00 (m, 18H), 7.82 (S, 2H). 2.88 (t, 8H), 2.52 (t, 4H), 1.58-1.29 (m, 16H), 0.88 (t, 6H).

### Synthesis Example 5: Synthesis of Compound 5

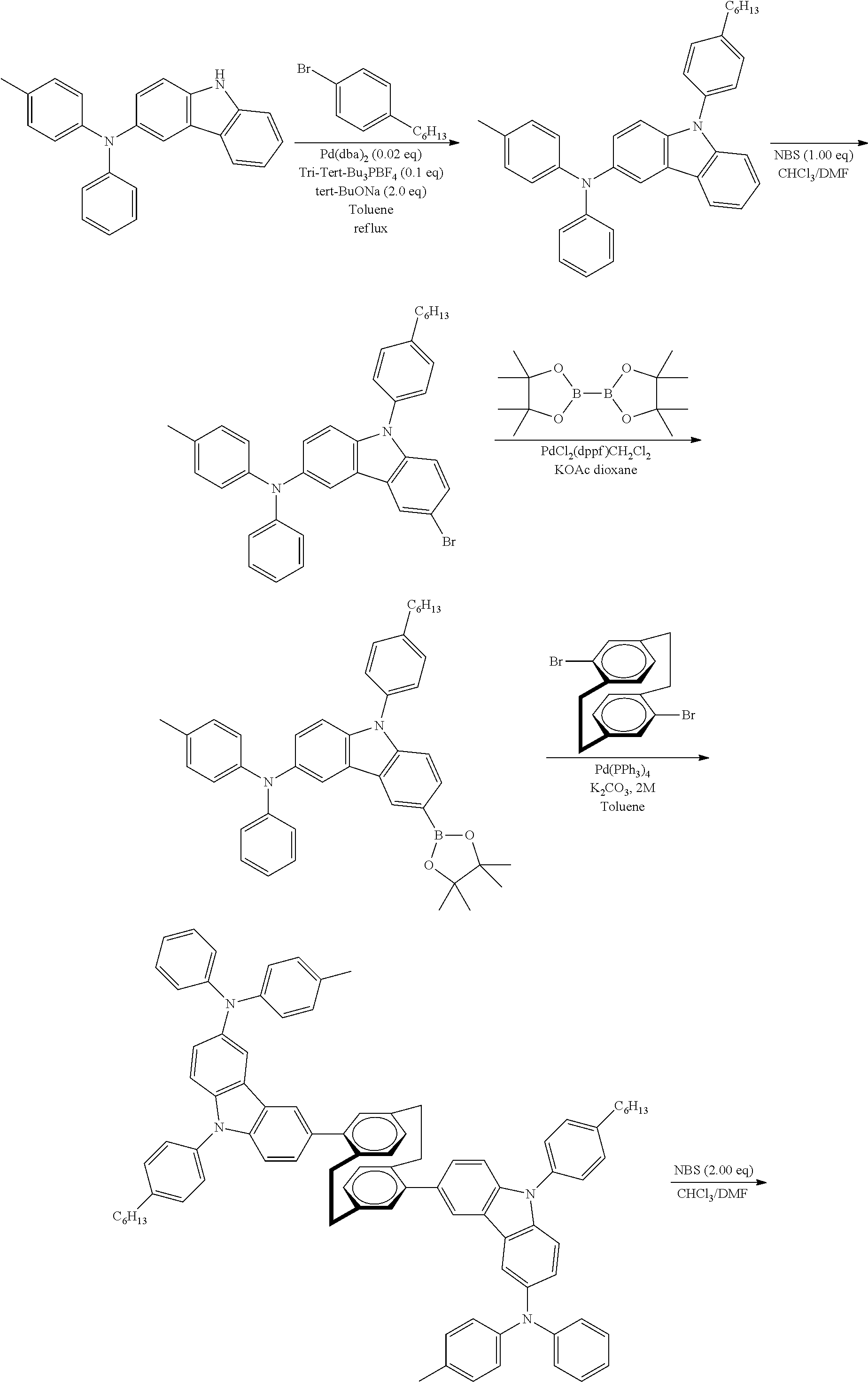

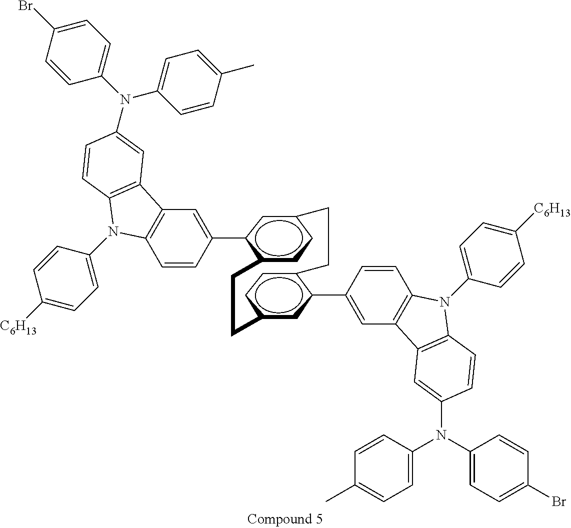

Compound 5 was synthesized in the same manner as in Synthesis of Compound 4.

### Example 1: Synthesis of Polymer A-1

Polymer A-1 including a repeating unit (A) and a repeating unit (B) having the following compositions was synthesized by using Compound 1 synthesized in Synthesis Example 1, Compound 2 synthesized in Synthesis Example 2, Compound 3 synthesized in Synthesis Example 3, and Compound 4 synthesized in Synthesis Example 4.

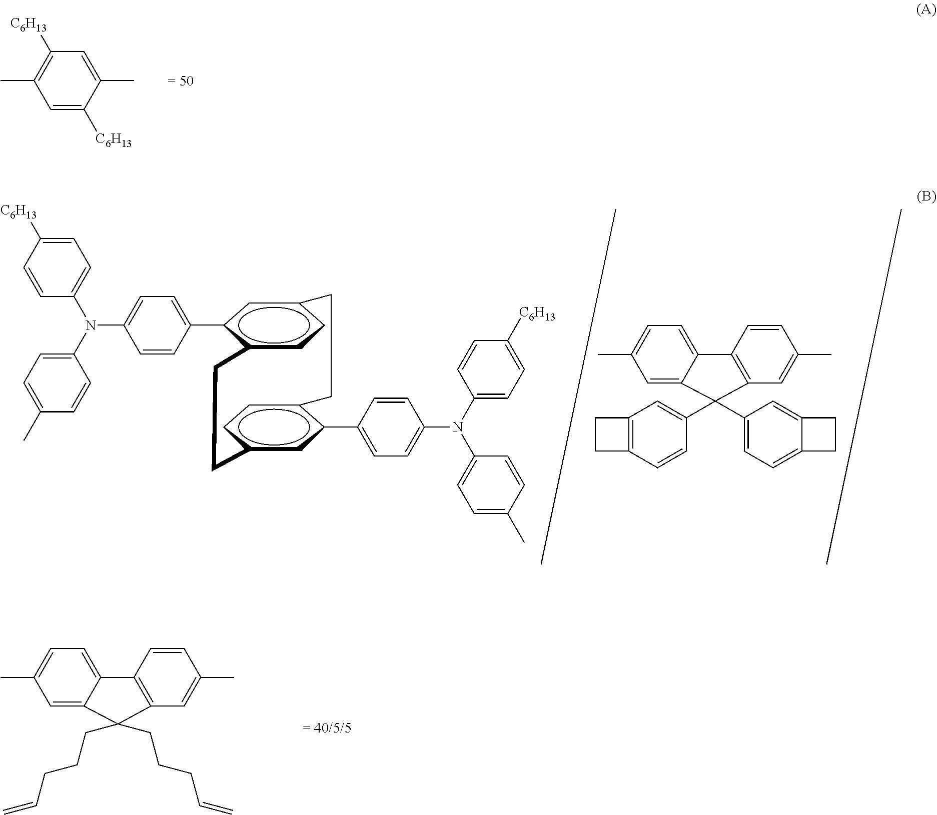

In an argon atmosphere, 1.96 g of Compound 1, 0.184 g of Compound 2, 0.211 g of Compound 3, 3.131 g of Compound 4, 4.3 mg of palladium acetate, 27.0 mg of tris(2-methoxyphenyl)phosphine, 55 mL of toluene, and 15.2 g of 20 wt % of tetraethylammonium hydroxide aqueous solution were added, and the mixture was refluxed for 8 hours. Then, 0.023 g of phenylboronic acid, 4.3 mg of palladium acetate, 27.0 mg of tris(2-methoxyphenyl)phosphine, and 15.2 g of 20 wt % of tetraethylammonium hydroxide aqueous solution were added, and the mixture was heated for 7 hours under reflux. Then, the water layer was removed, and 5.4 g of N, N-diethyldithiocarbamate sodium trihydrate and 50 ml of ion-exchanged water were added, and the mixture was stirred at a temperature of 85° C. for 2 hours. The organic layer was separated from the water layer and sequentially washed with water, 3 wt % of aqueous acetic acid solution, and water again. The organic layer was added dropwise to methanol to precipitate the polymer, which was filtered and dried to obtain a solid. The solid was dissolved in toluene, and passed through column chromatography packed with silica gel and alumina, and the solvent was distilled off under reduced pressure. A liquid obtained therefrom was added dropwise to methanol to precipitate a solid, and the solid was filtered, separated, and dried to obtain 0.79 g of polymer A-1.

The obtained polymer A-1 is presumed to be a polymer obtained by alternately polymerizing the repeating unit (A) and the repeating unit (B) in the above composition (repeating unit derived from Compound 1: repeating unit derived from Compound 4: repeating unit derived from Compound 3: repeating unit derived from Compound 2=50:40:5:5 (molar ratio)) based on the material ratio of the monomers. Also, the number average molecular weight (Mn), the weight average molecular weight (Mw), and the molecular weight distribution (Mw/Mn) of polymer A-1, which were estimated by size exclusion chromatography (SEC), were Mn=67,000, Mw=240,000, and Mw/Mn=3.58.

### Example 2: Synthesis of Polymer A-2

Polymer A-2 was synthesized in the same manner as in Example 1, except that Compound 5 was used instead of Compound 4. SEC analysis results of the obtained polymer were Mn=34,000, Mw=86,000, and Mw/Mn=2.53.

Triplet energy levels (electron volts, eV) of polymers A-1 and A-2 obtained in the above Examples and poly[(9,9-dioctylfluorenyl-2,7-diyl)-co-(4,4′-(N-(4-sec-butylphenyl)diphenylamine) (TFB) having the following structure (manufactured by Luminescence Technology Corp.) (Comparative Example 1) were measured by the following method, and results thereof are shown in Table 1.

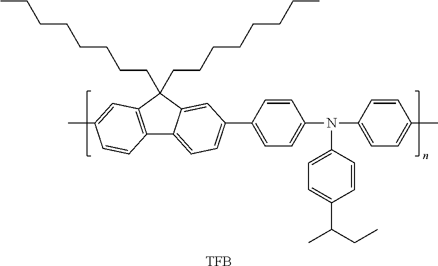

Measurement of Triplet Energy Level

Each Compound was dissolved in toluene to a concentration of 3.2 wt % to prepare a coating solution. The coating solution was applied at a rotating speed of 1,600 revolutions per minute (rpm) by spin coating, and dried on a hot plate at a temperature of 250° C. for 60 minutes to obtain a film (sample) having a thickness (dry film thickness) of about 70 nanometers (nm). The sample was cooled to a temperature of −196° C. and a photoluminescence (PL) spectrum thereof was measured. The triplet energy level (eV) was calculated from a peak value at the shortest wavelength side of the PL spectrum. Results thereof are shown in Table 1.

TABLE 1

| | | | | Triplet energy |
|---|---|---|---|---|
| | Polymer | Mn (×10⁴) | Mw (×10⁴) | level (eV) |
| Example 1 | A-1 | 6.7 | 24.0 | 2.70 |
| Example 2 | A-2 | 3.4 | 8.6 | 2.58 |
| Comparative | TFB | 8.6 | 18.3 | 2.30 |
| Example 1 | | | | |

From Table 1, it is confirmed that the polymer according to the embodiment has a higher triplet energy level, as compared with that of Comparative Example 1.

### Example 3: Manufacture of Organic Light-Emitting Device Device-1

First, on an ITO glass substrate on which stripe-shaped indium tin oxide (ITO) was deposited to a film thickness of 150 nm as an anode, PEDOT/PSS (product of Sigma-Aldrich) was spin-coated so as to have a dry film thickness of 30 nm to form a hole injection layer.

Then, polymer A-1 synthesized in Example 1 was dissolved in xylene (solvent) at a concentration of 1 wt % to prepare a coating liquid (A-1) for forming a hole transport layer. The coating liquid (A-1) for forming a hole transport layer was applied on the hole injection layer by spin coating, so that a thickness after drying was 30 nm, and heat treatment was performed thereon at a temperature of 230° C. for 1 hour to form a hole transport layer having a thickness (dry film thickness) of 30 nm.

Then, prepared was a toluene solution including Compound h-1 (6,9-diphenyl-9′-(5′-phenyl-[1,1′: 3′,1″-terphenyl]-3-yl)3,3′-bi[9H-carbazole) and Compound h-2 (3,9-diphenyl-5-(3-(4-phenyl-6-(5′-phenyl-[1,1′: 3′,1″-terphenyl]-3-yl)-1,3,5-triazine-2-yl)phenyl)-9H-carbazole) as a host material and tris(2-(3-p-xylyl)phenyl)pyridine iridium(III) (TEG) as a dopant. At this time, the toluene solution was prepared so that Compound h-1 had a concentration of 0.49 g/ml and Compound h-2 had a concentration of 0.05 g/ml. Also, an amount of the dopant was 10 wt % based on the total weight of the emission layer. The toluene solution was applied on the hole transport layer by spin coating so as to have a dry film thickness of 30 nm, thereby forming an emission layer.

Then, LiQ and KLET-03 (product of Chemipro Kasei) were co-deposited on the emission layer in a vacuum deposition apparatus to form an electron transport layer having a thickness of 50 nm.

Then, lithium fluoride (LiF) was deposited on the electron transport layer in the vacuum deposition apparatus to form an electron injection layer having a thickness of 1 nm.

Then, aluminum was deposited on the electron injection layer in the vacuum deposition apparatus to form a cathode having a thickness of 100 nm, thereby completing the manufacture of an organic light-emitting device Device-1.

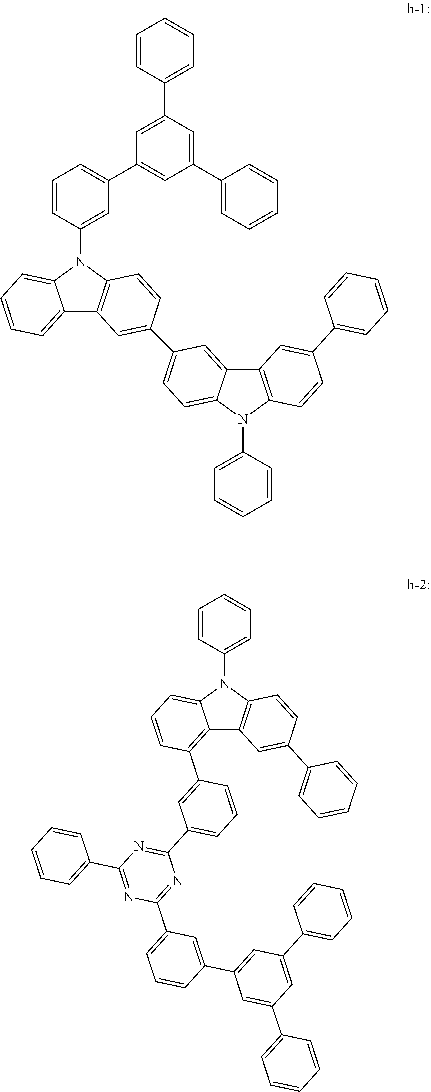 [SMILES: c1ccc(-c2cc(-c3ccccc3)cc(-c3cccc(-n4c5ccccc5c5cc(-c6ccc7c(c6)c6cc(-c8ccccc8)ccc6n7-c6ccccc6)ccc54)c3)c2)cc1 ; c1ccc(-c2cc(-c3ccccc3)cc(-c3cccc(-c4nc(-c5ccccc5)nc(-c5cccc(-c6cccc7c6c6cc(-c8ccccc8)ccc6n7-c6ccccc6)c5)n4)c3)c2)cc1]

### Example 4: Manufacture of Organic Light-Emitting Device Device-2

An organic light-emitting device Device-2 was manufactured in the same manner as in Example 3, except that polymer A-2 synthesized in Example 2 was used instead of polymer A-1.

### Comparative Example 2: Manufacture of Organic Light-Emitting Device Device-3

An organic light-emitting device Device-3 was manufactured in the same manner as in Example 3, except that TFB was used instead of polymer A-1.

The current efficiency and durability (emission lifespan) of the organic light-emitting devices manufactured according to Examples 3 and 4 and the organic light-emitting device manufactured according to Comparative Example 2 were evaluated according to the following method. Results of this evaluation are shown in Table 2 below. Also, in Table 2, the current efficiency of the organic light-emitting device Device-1 and Device-2 was a relative value when the current efficiency of the organic light-emitting device Device-3 manufactured according to Comparative Example 2 was 100. Also, the emission lifespan (durability) of the organic light-emitting devices Device-1 and Device-2 was a relative value (extension degree) when the organic light-emitting device Device-3 manufactured according to Comparative Example 2 was 100.

Evaluation of Current Efficiency and Durability (Emission Lifespan)

First, a DC constant voltage source (source meter, manufactured by KEYENCE) was used to apply a predetermined voltage to the respective organic light-emitting devices so as to make the organic light-emitting devices to emit light. While the light emission of the organic light-emitting device was measured by using a luminance measurement apparatus (SR-3, manufactured by Topcom), a current applied to the organic light-emitting device was gradually increased. A current at which luminance reached 1,000 candelas per square meter (cd/m²) was constantly maintained.

The current efficiency (cd/A) was calculated by calculating a current value per unit area of the organic light-emitting device (a current density) and dividing luminance (cd/m²) by the current density (amperes per square meter, A/m²).

The emission lifespan (hour, hr) indicates an amount of time that lapsed when luminance measured by the measurement apparatus was reduced to 80% of initial luminance (100%). Also, the current efficiency indicates efficiency (conversion efficiency) of converting a current into luminescence energy. As the current efficiency is higher, the organic light-emitting device has higher performance.

TABLE 2

| | Organic light- | Hole transport | Current | Emission |
|---|---|---|---|---|
| | emitting device | material | efficiency | lifespan |
| Example 3 | Device-1 | A-1 | 254 | 600 |
| Example 4 | Device-2 | A-2 | 313 | 250 |
| Comparative | Device-3 | TFB | 100 | 100 |
| Example 2 | | | | |

From Table 2, it is confirmed that the organic light-emitting devices Device-1 and Device-2 of Examples 3 and 4 are excellent in terms of both current efficiency and emission lifespan, as compared with the organic light-emitting device Device-3 of Comparative Example 2. Therefore, the polymer according to one or more embodiments may be suitably used for the organic light-emitting device (in particular, a hole transport material).

Also, the polymer according to one or more embodiments may enable efficient film formation using solution coating and mass production and may also improve the lifespan of the organic light-emitting device.

According to one or more embodiments, the polymer may have a high triplet energy level, and the organic light-emitting device including the polymer may have improved luminescent efficiency and current efficiency.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. A polymer comprising at least one first repeating unit represented by Formula 1: 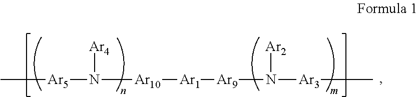
wherein, in Formula 1,
Ar₂ and Ar₄ are each independently selected from hydrogen, a substituted or unsubstituted C₁-C₂₉ alkyl group, a substituted or unsubstituted C₃-C₁₆ cycloalkyl group, a substituted or unsubstituted C₁-C₂₉ alkoxy group, a substituted or unsubstituted C₃-C₁₆ cycloalkoxy group, a substituted or unsubstituted C₆-C₃₀ aryl group, a substituted or unsubstituted C₆-C₃₉ aryloxy group, a substituted or unsubstituted C₇-C₄₀ aralkyl group, a substituted or unsubstituted monovalent C₅-C₃₀ heterocyclic group, and —N(Q₁)(Q₂),
at least one of Ar₂ and Ar₄ is selected from a substituted or unsubstituted C₁-C₂₀ alkyl group, a substituted or unsubstituted C₃-C₁₆ cycloalkyl group, a substituted or unsubstituted C₁-C₂₉ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₉ aralkyl group, a substituted or unsubstituted monovalent C₅-C₃₀ heterocyclic group, and —N(Q₁)(Q₂),
Ar₃ and Ar₅ are each independently selected from a substituted or unsubstituted divalent C₆-C₃₉ carbocyclic group and a substituted or unsubstituted divalent C₅-C₃₀ heterocyclic group,
at least one of Ar₂ and Ar₃ is optionally linked to Ar₉ to form a ring structure,
at least one of Ar₄ and Ar₅ is optionally linked to Ar₁₀ to form a ring structure,
m and n are each independently an integer greater than or equal to 1,
when m is two or more, two or more groups Ar₂ are identical to or different from each other, when m is two or more, two or more groups Ar₃ are identical to or different from each other, when n is two or more, two or more groups Ar₄ are identical to or different from each other, and when n is two or more, two or more groups Ar₅ are identical to or different from each other,
Ar₉ and Ar₁₀ are each independently selected from a single bond, a substituted or unsubstituted divalent C₆-C₃₀ carbocyclic group, and a substituted or unsubstituted divalent C₅-C₃₀ heterocyclic group,
at least one of Ar₉ and Ar₁₀ is selected from a substituted or unsubstituted divalent C₆-C₃₀ carbocyclic group and a substituted or unsubstituted divalent C₅-C₃₀ heterocyclic group, and
Ar₁ is a divalent group represented by Formula 1-1: 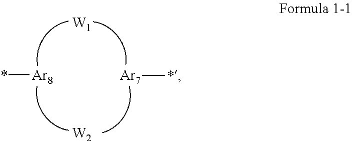
wherein, in Formula 1-1,
W₁ and W₂ are each independently a divalent linking group represented by —X—Z— or —Z—X—,
X is a substituted or unsubstituted C₁-C₂₀ alkylene group, a substituted or unsubstituted C₂-C₂₀ alkenylene group, a substituted or unsubstituted C₂-C₂₀ alkynylene group, a substituted or unsubstituted C₃-C₁₆ cycloalkylene group, a substituted or unsubstituted C₃-C₁₆ cycloalkenylene group, or a substituted or unsubstituted C₆-C₃₀ arylene group,
Z is a single bond, —O—, —C(═O)—, —N(Q₃)-, —S—, —S(═O)₂—, or —Si(Q₃)(Q₄)-,
Ar₇ and Ar₈ are each independently selected from a substituted or unsubstituted trivalent C₆-C₃₀ carbocyclic group and a substituted or unsubstituted trivalent C₅-C₃₀ heterocyclic group,
at least one of Are to Ar₅ is optionally linked to Ar₇ or Ar₈ to form a ring structure,
Q₁ and Q₂ are each independently selected from hydrogen, a substituted or unsubstituted C₁-C₂₀ alkyl group, and a substituted or unsubstituted C₆-C₃₀ aryl group,
Q₃ and Q₄ are each independently selected from hydrogen and a substituted or unsubstituted C₁-C₈ alkyl group,
at least one substituent of the substituted C₁-C₂₀ alkyl group, the substituted C₃-C₁₆ cycloalkyl group, the substituted C₁-C₂₀ alkoxy group, the substituted C₃-C₁₆ cycloalkoxy group, the substituted C₆-C₃₀ aryl group, the substituted C₆-C₃₀ aryloxy group, the substituted C₇-C₄₀ aralkyl group, the substituted monovalent C₅-C₃₀ heterocyclic group, the substituted C₁-C₂₀ alkylene group, the substituted C₂-C₂₀ alkenylene group, the substituted C₂-C₂₀ alkynylene group, the substituted C₃-C₁₆ cycloalkylene group, the substituted C₃-C₁₆ cycloalkenylene group, the substituted C₆-C₃₀ arylene group, the substituted divalent C₆-C₃₀ carbocyclic group, the substituted divalent C₅-C₃₀ heterocyclic group, the substituted trivalent C₆-C₃₀ carbocyclic group, and the substituted trivalent C₅-C₃₀ heterocyclic group is selected from:
deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and
—Si(Q₃₁)(Q₃₂)(Q₃₃), —N(Q₃₄)(Q₃₅), and —B(Q₃₆)(Q₃₇),
Q₁₁ to Q₁₇, Q₂₁ to Q₂₇, and Q₃₁ to Q₃₇ are each independently selected from hydrogen, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and
and *′ each indicate a binding site to a neighboring atom.

2. The polymer of claim 1, wherein
at least one of Ar₂ and Ar₄ is selected from a substituted or unsubstituted C₆-C₃₀ aryl group and a substituted or unsubstituted monovalent C₅-C₃₀ heterocyclic group.

3. The polymer of claim 1, wherein
Ar₂ and Ar₄ are each independently selected from:
hydrogen, a methyl group, an ethyl group, an n-propyl group, an iso-propyl group, an n-butyl group, an iso-butyl group, a sec-butyl group, a tert-butyl group, an n-pentyl group, an isopentyl group, a tert-pentyl group, a neo-pentyl group, a 1,2-dimethylpropyl group, an n-hexyl group, an iso-hexyl group, a 1,3-dimethylbutyl group, a 1-iso-propylpropyl group, a 1,2-dimethylbutyl group, an n-heptyl group, a 1,4-dimethylpentyl group, a 3-ethylpentyl group, a 2-methyl-1-iso-propylpropyl group, a 1-ethyl-3-methylbutyl group, an n-octyl group, a 2-ethylhexyl group, a 3-methyl-1-iso-propylbutyl group, a 2-methyl-1-iso-propyl group, a 1-tert-butyl-2-methylpropyl group, an n-nonyl group, a 3,5,5-trimethyldecyl group, an n-decyl group, an iso-decyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, an n-eicosyl group, an n-heneicosyl group, an n-docosyl group, an n-tricosyl group, an n-tetracosyl group, a methoxy group, an ethoxy group, a propoxy group, an iso-propoxy group, an n-butoxy group, an iso-butoxy group, a sec-butoxy group, tert-butoxy group, an n-pentoxy group, an iso-pentoxy group, a tert-pentoxy group, a neo-pentoxy group, an n-hexyloxy group, an iso-hexyloxy group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, a cyclopropyl group, a cyclobutyl group, a cyclopentyl group, a cyclohexyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a thoxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group;
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryloxy group, a C₆-C₃₀ arylthio group, and a C₅-C₃₀ heteroaryl group.

4. The polymer of claim 1, wherein
Ar₃ and Ar₅ are each independently selected from:
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahygrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoxazolylene group, a benzimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, an imidazopyrimidinylene group, and an imidazopyridinylene group; and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group.

5. The polymer of claim 1, wherein
Ar₃ and Ar₉ and/or Ar₅ and Ar₁₀ are linked to form a ring structure.

6. The polymer of claim 1, wherein
Ar₇ and Ar₈ are each independently selected from:
a benzene group, a pentalene group, an indene group, a naphthalene group, an azulene group, a heptalene group, an indacene group, an acenaphthalene group, a fluorene group, a spiro-fluorene group, a phenalene group, a phenanthrene group, an anthracene group, a fluoranthene group, a pyrene group, a chrysene group, a naphthacene group, a picene group, a perylene group, a pentaphenylene group, a hexacene group, a pyrrole group, an imidazole group, a pyrazole group, a pyridine group, a pyrazine group, a pyrimidine group, a pyridazine group, an iso-indole group, an indole group, an indazole group, a purine group, a quinoline group, an isoquinoline group, a benzoquinoline group, a phthalazine group, a naphthyridine group, a quinoxaline group, a quinazoline group, a cinnoline group, a carbazole group, a phenanthridine group, an acridine group, a phenanthroline group, a phenazine group, a benzoxazole group, a benzimidazole group, a furan group, a benzofuran group, a thiophene group, a benzothiophene group, a thiazole group, an isothiazole group, a benzothiazole group, an iso-oxazole group, an oxazole group, a triazole group, a tetrazole group, an oxadiazole group, a triazine group, a dibenzofuran group, a dibenzothiophene group, a benzocarbazole group, a dibenzocarbazole group, an imidazopyrimidine group, and an imidazopyridine group; and
a benzene group, a pentalene group, an indene group, a naphthalene group, an azulene group, a heptalene group, an indacene group, an acenaphthalene group, a fluorene group, a spiro-fluorene group, a phenalene group, a phenanthrene group, an anthracene group, a fluoranthene group, a pyrene group, a chrysene group, a naphthacene group, a picene group, a perylene group, a pentaphenylene group, a hexacene group, a pyrrole group, an imidazole group, a pyrazole group, a pyridine group, a pyrazine group, a pyrimidine group, a pyridazine group, an iso-indole group, an indole group, an indazole group, a purine group, a quinoline group, an isoquinoline group, a benzoquinoline group, a phthalazine group, a naphthyridine group, a quinoxaline group, a quinazoline group, a cinnoline group, a carbazole group, a phenanthridine group, an acridine group, a phenanthroline group, a phenazine group, a benzoxazole group, a benzimidazole group, a furan group, a benzofuran group, a thiophene group, a benzothiophene group, a thiazole group, an isothiazole group, a benzothiazole group, an iso-oxazole group, an oxazole group, a triazole group, a tetrazole group, an oxadiazole group, a triazine group, a dibenzofuran group, a dibenzothiophene group, a benzocarbazole group, a dibenzocarbazole group, an imidazopyrimidine group, and an imidazopyridine group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with C₁-C₂₀ alkyl group, a C₆-C₃₀ aryloxy group, a C₆-C₃₀ arylthio group, and a C₅-C₃₀ heteroaryl group.

7. The polymer of claim 1, wherein
W₁ and W₂ are each independently a divalent group represented by —((CR₁R₂)_{q})—,
R₁ and R₂ are each independently selected from hydrogen, a substituted or unsubstituted C₁-C₂₀ alkyl group, a substituted or unsubstituted C₃-C₁₆ cycloalkyl group, a substituted or unsubstituted C₁-C₂₀ alkoxy group, a substituted or unsubstituted C₃-C₁₆ cycloalkoxy group, a substituted or unsubstituted C₆-C₃₀ aryl group, a substituted or unsubstituted C₆-C₃₀ aryloxy group, a substituted or unsubstituted C₇-C₄₀ aralkyl group, a substituted or unsubstituted C₅-C₃₀ heteroaryl group, and —N(Q₁)(Q₂), and
q is an integer from 1 to 4.

8. The polymer of claim 1, wherein
Formula 1-1 is a divalent group represented by Formula 1-2: 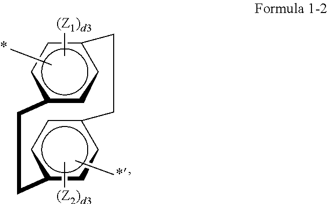
wherein, in Formula 1-2,
Z₁ and Z₂ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl, a C₆-C₃₀ aryloxy group, a C₆-C₃₀ arylthio group, and a C₅-C₃₀ heteroaryl group,
d3 is an integer from 1 to 3, and
and *′ each indicate a binding site to a neighboring atom.

9. The polymer of claim 1, wherein
Formula 1-1 is selected from groups represented by Formulae 4-1 to 4-4: 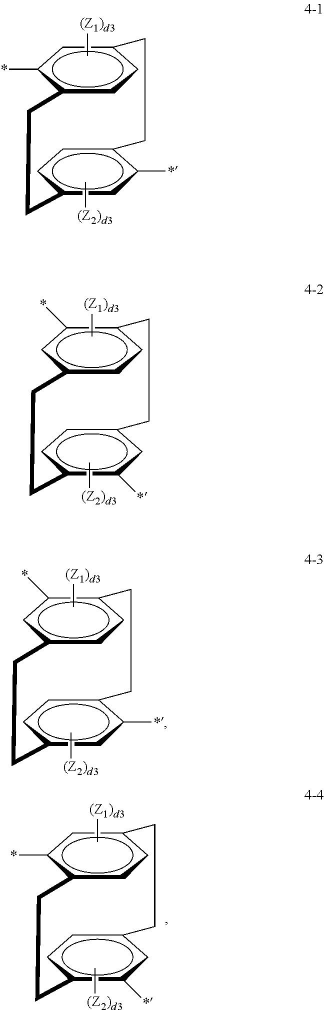
wherein, in Formulae 4-1 to 4-4,
Z₁ and Z₂ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,
d3 is an integer from 1 to 3, and
and *′ each indicate a binding site to a neighboring atom.

10. The polymer of claim 1, wherein
Ar₉ and Ar₁₀ are each independently selected from:
a single bond, a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoxazolylene group, a benzimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, an imidazopyrimidinylene group, and an imidazopyridinylene group; and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, an epoxy group, an aziridine group, a thiirane group, an oxetane group, an azetidine group, a thiethane group, a tetrahydrofuran group, a dioxolane group, a pyrrolidine group, a pyrazolidine group, an imidazolidine group, an oxazolidine group, a tetrahydrothiophene group, a sulfolane group, a thiazolidine group, an ε-caprolactone group, an ε-caprolactam group, a piperidine group, a hexahydropyridazine group, a hexahydropyrimidine group, a piperazine group, a morpholine group, a tetrahydropyran group, a 1,3-dioxane group, a 1,4-dioxane group, a trioxane group, a tetrahydrothiopyran group, a thiomorpholine group, a thiomorpholine-1,1-dioxide group, a pyranose group, a diazabicyclo[2,2,2]-octane group, a phenoxazine group, a phenothiazine group, an oxanthrene group, a thioxanthene group, a phenoxathiin group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridimidinyl group, and an imidazopyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group.

11. The polymer of claim 1, wherein
Ar₉ and Ar₁₀ are each independently selected from divalent groups represented by Formulae 5-1 to 5-5: 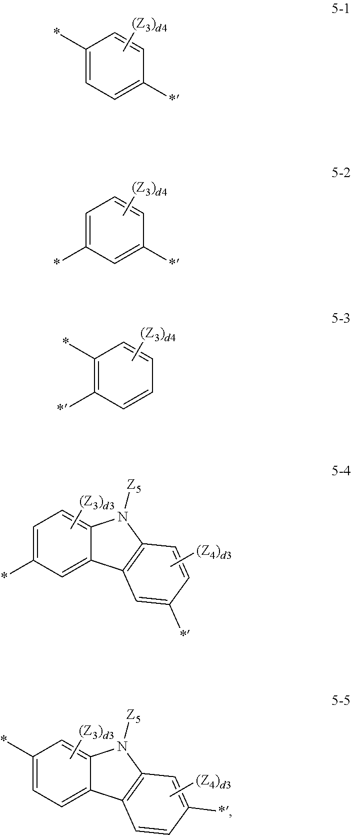
wherein, in Formulae 5-1 to 5-5,
Z₃ to Z₅ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₉ aryl group substituted with a C₁-C₂₉ alkyl group, a C₆-C₃₉ aryloxy group, a C₆-C₃₉ arylthio group, and a C₅-C₃₉ heteroaryl group,
d3 is an integer from 1 to 3,
d4 is an integer from 1 to 4, and
and *′ each indicate a binding site to a neighboring atom.

12. The polymer of claim 1, wherein
Formula 1-1 is selected from divalent groups represented by Formulae 4-1 to 4-4, and
Ar₉ and Ar₁₀ are each independently selected from divalent groups represented by Formulae 5-1 to 5-5: 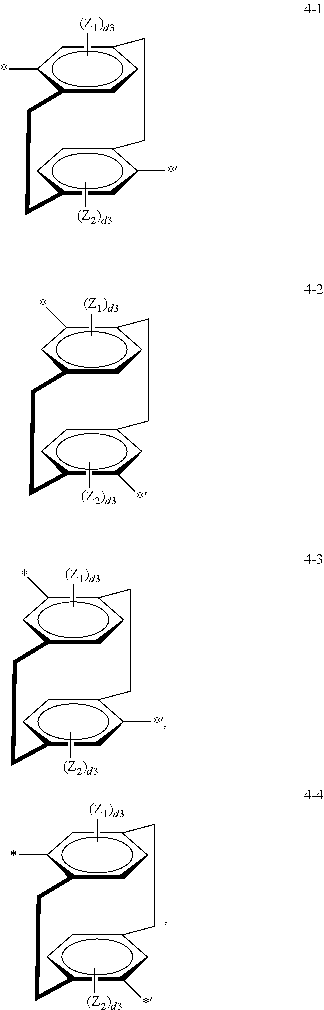 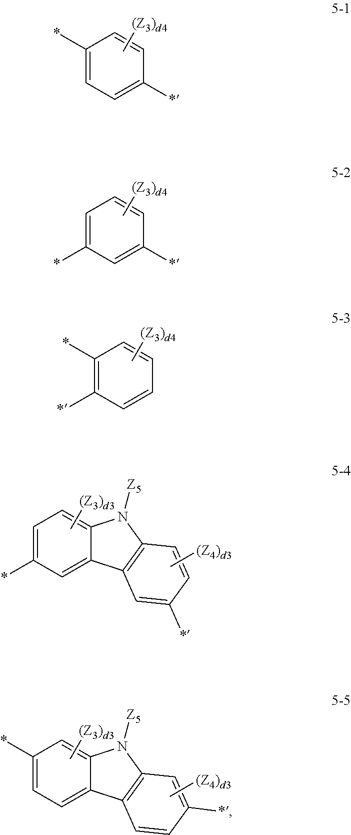
wherein, in Formulae 4-1 to 4-4 and 5-1 to 5-5,
Z₁ to Z₅ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₉ alkenyl group, a C₂-C₂₉ alkynyl group, a C₃-C₁₆ cycloalkyl group, a C₁-C₂₀ alkoxy group, a C₃-C₁₆ cycloalkoxy group, a C₆-C₃₀ aryl group, a C₆-C₃₀ aryl group substituted with a C₁-C₂₀ alkyl group, a C₆-C₃₀ aryloxy group, a C₆-C₃₀ arylthio group, and a C₅-C₃₀ heteroaryl group,
d3 is an integer from 1 to 3,
d4 is an integer from 1 to 4, and
and *′ each indicate a binding site to a neighboring atom.

13. The polymer of claim 1, wherein
the polymer further comprises at least one of a second repeating unit represented by Formula 2 and a third repeating unit represented by Formula 3: 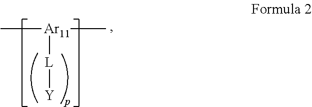
wherein, in Formula 2,
Ar₁₁ is a substituted or unsubstituted (2+p)-valent C₆-C₃₀ carbocyclic group or a substituted or unsubstituted (2+p)-valent C₅-C₃₀ heterocyclic group,
L is a single bond, a substituted or unsubstituted C₁-C₂₄ alkylene group, or a substituted or unsubstituted phenylene group,
Y is a crosslinking group,
p is an integer greater than or equal to 1, and
when p is two or more, two or more groups L are identical to or different from each other, and when p is two or more, two or more groups Y are identical to or different from each other: 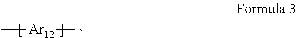
wherein, in Formula 3,
Ar₁₂ is a substituted or unsubstituted divalent C₆-C₃₀ carbocyclic group or a substituted or unsubstituted divalent C₅-C₃₀ heterocyclic group.

14. The polymer of claim 13, wherein
Ar₁₁ in Formula 2 is selected from:
a phenylene group, a fluorenylene group, a dibenzofuranylene group, a dibenzothiophenylene group, and a triphenylenylene group; and
a phenylene group, a fluorenylene group, a dibenzofuranylene group, a dibenzothiophenylene group, and a triphenylenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a fluorenyl group, a dibenzofuranyl group, a dibenzothiophenyl group, and a triphenylenyl group.

15. The polymer of claim 13, wherein
Y in Formula 2 is at least one selected from groups represented by Formulae 9-1 to 9-8: 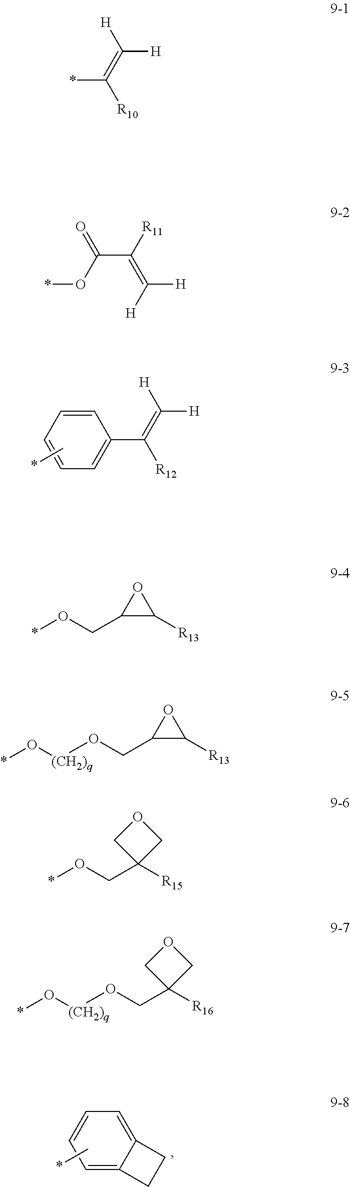
wherein in Formulae 9-1 to 9-8,
R₁₀ to R₁₆ are each independently selected from hydrogen and a substituted or unsubstituted C₁-C₁₀ alkyl group,
q is an integer from 1 to 10, and
indicates a binding site to a neighboring atom.

16. The polymer of claim 13, wherein
Ar₁₂ in Formula 3 is selected from:
a phenylene group, a naphthylene group, a phenanthrenylene group, a triphenylene group, a pyridinylene group, a pyrimidinylene group, and a triazinylene group; and
a phenylene group, a naphthylene group, a phenanthrenylene group, a triphenylene group, a pyridinylene group, a pyrimidinylene group, and a triazinylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₄ alkyl group, a C₁-C₂₄alkoxy group, a phenyl group, a naphthyl group, a phenanthrenyl group, a triphenyl group, a pyridinyl group, a pyrimidinyl group, and a triazinyl group.

17. A composition comprising:
the polymer of claim 1; and
a solvent or a dispersion medium.

18. An organic light-emitting device comprising:
a first electrode;
a second electrode; and
an organic layer disposed between the first electrode and the second electrode and comprising an emission layer,
wherein the organic layer comprises the polymer of claim 1.

19. The organic light-emitting device of claim 18, wherein
the emission layer comprises a phosphorescent dopant.

20. The organic light-emitting device of claim 18, wherein
the organic layer comprises a hole transport layer, and
the hole transport layer comprises the polymer.
